(19) United States
(12) Patent Application Publication
(10) Pub. No.: US 2025/0324727 A1
(43) Pub. Date: Oct. 16, 2025

(54) SEMICONDUCTOR DEVICE AND METHODS OF FORMATION

(71) Applicant: Taiwan Semiconductor Manufacturing Company, Ltd, Hsinchu (TW)

(72) Inventors: Shu-Uei JANG, Hsinchu City (TW); Chung-Shu WU, Taoyuan City (TW)

(21) Appl. No.: 18/636,904

(22) Filed: Apr. 16, 2024

(51) Int. Cl. H01L 21/8234; H01L 21/3065; H01L 27/088; H01L 29/06; H01L 29/417; H01L 29/423; H01L 29/66; H01L 29/775; H01L 29/786

(52) U.S. Cl. CPC H10D 84/013; H01L 21/3065; H10D 30/014; H10D 30/43; H10D 30/6735; H10D 30/6757; H10D 62/121; H10D 64/018; H10D 64/258; H10D 84/038; H10D 84/83

(57) ABSTRACT

A multiple-etch process is performed to form cavities in which inner spacers of a nanostructure transistor are to be formed. The multiple-etch process includes one or more first etch operations to form the cavities, and one or more second etch operations to trim the corners of the cavities to reduce corner rounding in the corners of the cavities. The corners of the cavities have greater orthogonality between the sidewalls and inner surface of the cavities as a result of the one or more second etch operations being performed. This results in increased uniformity in the lateral thickness of the inner spacers that are subsequently formed in the cavities. The increased uniformity in the lateral thickness of the inner spacers reduces the likelihood of etching through any particular part of the inner spacers during a replacement gate operation to replace sacrificial nanostructure layers with the gate structure of the nanostructure transistor.

### BACKGROUND

As semiconductor device manufacturing advances and technology processing nodes decrease in size, transistors may become affected by short channel effects (SCEs) such as hot carrier degradation, barrier lowering, and quantum confinement, among other examples. In addition, as the gate length of a transistor is reduced for smaller technology nodes, source/drain (S/D) electron tunneling increases, which increases the off current for the transistor (the current that flows through the channel of the transistor when the transistor is in an off configuration). Silicon (Si)/silicon germanium (SiGe) nanostructure transistors such as nanowires, nanosheets, and gate-all-around (GAA) devices are potential candidates to overcome short channel effects at smaller technology nodes. Nanostructure transistors are efficient structures that may experience reduced SCEs and enhanced carrier mobility relative to other types of transistors.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of an example implementation of a fin definition process described herein.

FIG. 2 is a diagram of an example dummy gate structure formation process described herein.

FIG. 3 is a diagram of an example implementation of a source/drain recess formation process described herein.

FIGS. 4A-4D are diagrams of an example implementation of an inner spacer formation process described herein.

FIG. 5 is a diagram of an example implementation of a source/drain region formation process described herein.

FIG. 6 is a diagram of an example implementation of an interlayer dielectric formation process described herein.

FIGS. 7A and 7B are diagrams of an example implementation of a replacement gate process described herein.

FIG. 8 is a diagram of an example of a semiconductor device described herein.

FIGS. 9 and 10 are flowcharts of example processes associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some nanostructure transistors (e.g., nanowire transistors, nanosheet transistors, gate-all-around (GAA) transistors, multi-bridge channel transistors, nanoribbon transistors, and/or other types of nanostructure transistors) include inner spacers between a source/drain region and a gate structure. The inner spacers may provide various process and/or performance benefits, such as electrical isolation between the source/drain region and the gate structure, and/or protections of the source/drain region from being etched during a replacement gate operation to replace sacrificial nanostructure layers with the gate structure.

However, the process of forming the inner spacers can be challenging and may result in defects in the inner spacers that reduce the ability of the inner spacers to provide electrical isolation and/or to protect the source/drain regions from etching. For example, corner rounding may occur when forming cavities in which inner spacers are to be formed for a nanostructure transistor, and this corner rounding may result in reduced lateral thickness at the top and bottom ends of the inner spacers. The reduced lateral thickness of the inner spacers may result in less of an etch buffer or etch stop when the replacement gate operation is performed, and etching through the inner spacers and into the source/drain region may occur, thereby damaging the source/drain region and/or resulting in electrical shorting between the source/drain region and the gate structure. This may lead to failure of the nanostructure transistor and may lead to reduced yield of nanostructure transistors on a semiconductor device.

In some implementations described herein, inner spacers are formed in a nanostructure transistor of a semiconductor device in a manner that reduces the likelihood of etching through the inner spacers and into an adjacent source/drain region. In particular, a multiple-etch process described herein is performed to form the cavities in which the inner spacers are to be formed. The multiple-etch process includes one or more first etch operations to form the cavities, and one or more second etch operations to trim the corners of the cavities to reduce corner rounding in the corners of the cavities. The corners of the cavities have sharper transitions (e.g., increased orthogonality) between the sidewalls and an inner surface of the cavities as a result of the one or more second etch operations being performed. This results in less variation and increased uniformity in the lateral thickness of the inner spacers that are subsequently formed in the cavities. The increased uniformity in the lateral thickness of the inner spacers reduces the likelihood of etching through any particular part of the inner spacers during a replacement gate operation to replace sacrificial nanostructure layers with the gate structure of the nanostructure transistor. In this way, the techniques described herein may reduce the likelihood of failure of the nanostructure transistor and/or may increase the yield of nanostructure transistors formed on the semiconductor device.

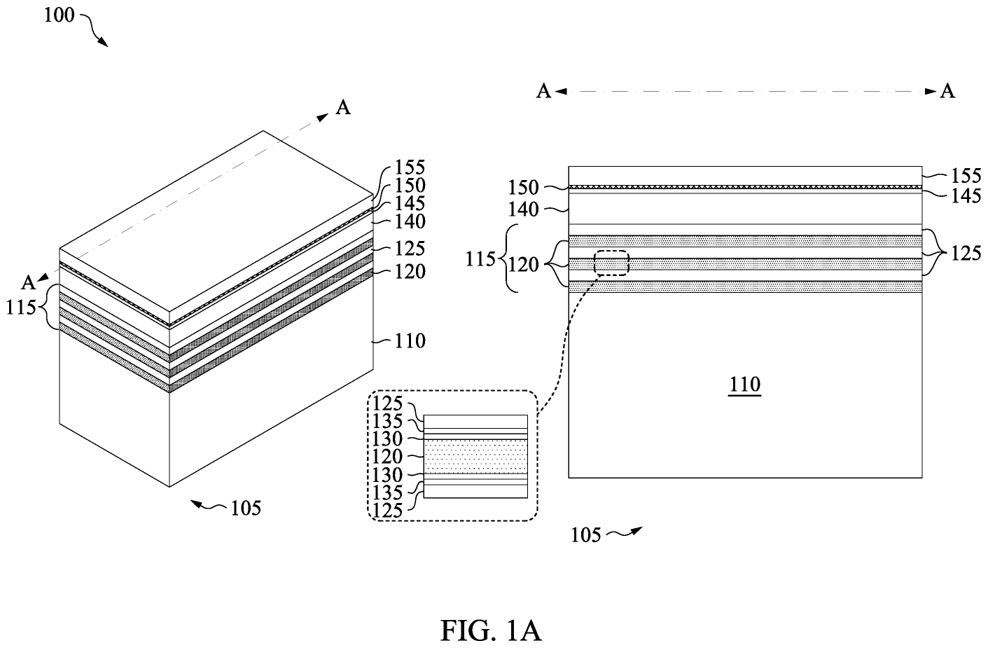

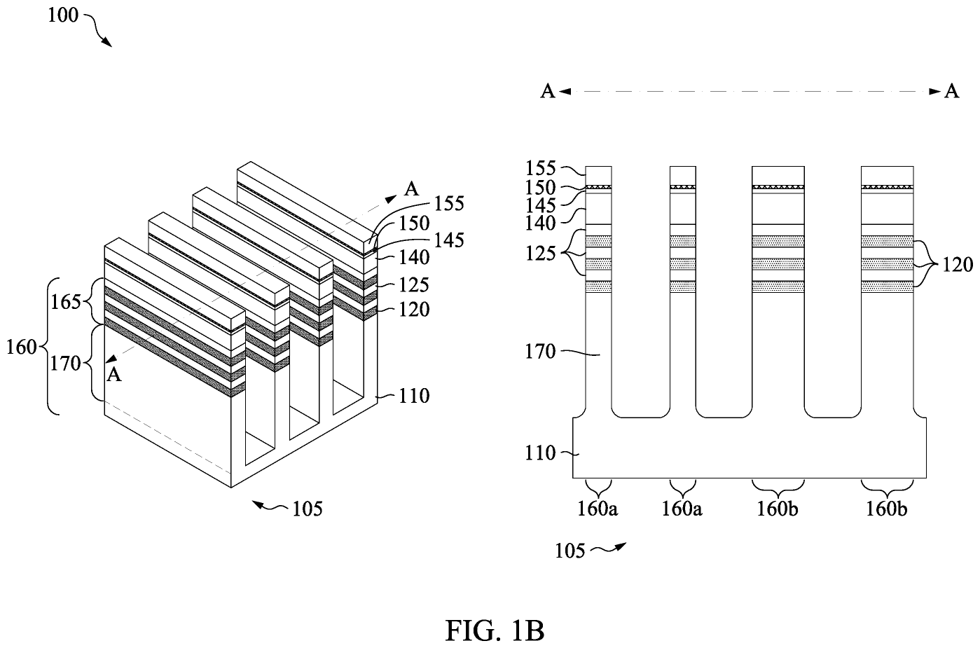

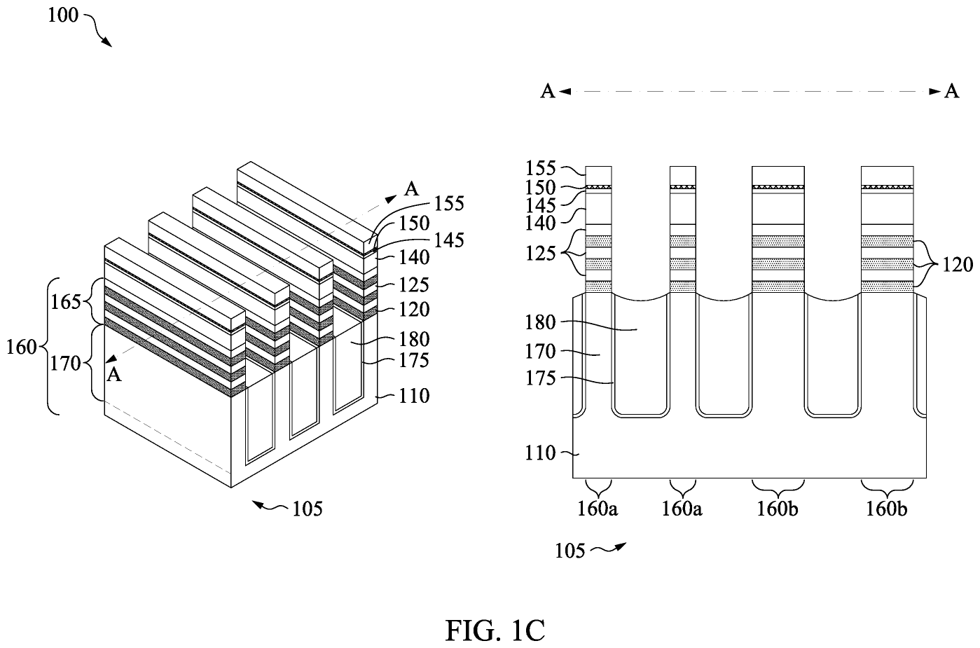

FIGS. 1A-1C are diagrams of an example implementation 100 of a fin definition process described herein. The example implementation 100 includes an example of forming fin structures and associated shallow trench isolation (STI) regions for a semiconductor device 105 described herein. The semiconductor device 105 may be manufactured to include one or more transistors. The one or more transistors may include nanostructure transistor(s) such as nanowire transistors, nanosheet transistors, gate-all-around (GAA) transistors, multi-bridge channel transistors, nanoribbon transistors, and/or other types of nanostructure transistors. The example implementation 100 includes an example of forming the fin structures and the associated STI regions for the transistors of the semiconductor device 105.

FIGS. 1A-1C each illustrate a perspective view of the semiconductor device 105 and a cross-sectional view along the line A-A in the perspective view. As shown in FIGS. 1A, processing of the semiconductor device 105 is performed in connection with a semiconductor substrate 110. The semiconductor substrate 110 includes a silicon (Si) substrate, a substrate formed of a material including silicon, a III-V compound semiconductor material substrate such as gallium arsenide (GaAs), a silicon on insulator (SOI) substrate, a germanium (Ge) substrate, a silicon germanium (SiGe) substrate, a silicon carbide (SiC) substrate, or another type of semiconductor substrate.

A layer stack 115 is formed on the semiconductor substrate 110. The layer stack 115 may be referred to as a superlattice. The layer stack 115 includes a plurality of alternating layers that are arranged in a direction (e.g., the z-direction) that is approximately perpendicular to the semiconductor substrate 110. For example, the layer stack 115 includes vertically alternating layers of sacrificial nanostructure layers 120 and nanostructure channel layers 125 above the semiconductor substrate 110. The quantity of the sacrificial nanostructure layers 120 and the quantity of the nanostructure channel layers 125 illustrated in FIG. 1A are examples, and other quantities of the sacrificial nanostructure layers 120 and the nanostructure channel layers 125 are within the scope of the present disclosure.

The sacrificial nanostructure layers 120 enable a vertical distance to be defined between adjacent nanostructure channels that are formed from the nanostructure channel layers 125, and serve as placeholder layers for subsequently-formed gate structures of the transistors of the semiconductor device 105 that are formed around the nanostructure channels. The sacrificial nanostructure layers 120 include a first material composition, and the nanostructure channel layers 125 include a second material composition. In some implementations, the first material composition and the second material composition are the same material composition. In some implementations, the first material composition and the second material composition are different material compositions. As an example, the sacrificial nanostructure layers 120 may include silicon germanium (SiGe) and the nanostructure channel layers 125 may include silicon (Si). This enables the sacrificial nanostructure layers 120 and/or the nanostructure channel layers 125 to be selectively etched (e.g., enables the sacrificial nanostructure layers 120 and not the nanostructure channel layers 125 to be etched, enables the nanostructure channel layers 125 and not the sacrificial nanostructure layers 120 to be etched) depending on the type of etchant that is used.

One or more types of deposition tools may be used to deposit and/or grow the alternating layers of the layer stack 115 to include nanostructures (e.g., nanosheets) on the semiconductor substrate 110. For example, a deposition tool may be used to grow the sacrificial nanostructure layers 120 and/or the nanostructure channel layers 125 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial nanostructure layers 120 and/or the nanostructure channel layers 125 may be deposited by chemical vapor deposition (CVD), physical vapor deposition (PVD), atomic layer deposition (ALD), and/or another suitable deposition technique.

As shown in a close-up view in FIG. 1A of a portion of the layer stack 115, intermixing between two or more nanostructure layers in the layer stack 115 may occur. For example, intermixing may occur between a sacrificial nanostructure layer 120 and a vertically adjacent nanostructure channel layer 125. The intermixing may result in diffusion of silicon (Si) and/or germanium (Ge) between the sacrificial nanostructure layer 120 and the nanostructure channel layer 125. Thus, a silicon germanium region 130 may be included between the sacrificial nanostructure layer 120 and the nanostructure channel layer 125. The silicon germanium region 130 may include a region of silicon germanium (SiGe) having a greater concentration of silicon (Si) (e.g., due to the diffusion of silicon from the nanostructure channel layer 125 into the sacrificial nanostructure layer 120) than the concentration of silicon in the sacrificial nanostructure layer 120. In some implementations, the silicon germanium region 130 is a region within the sacrificial nanostructure layer 120.

A silicon region 135 may be included between the silicon germanium region 130 and the nanostructure channel layer 125. The silicon region 135 may include a region of silicon (Si) having a greater concentration of germanium (Ge) (e.g., due to the diffusion of silicon germanium from the sacrificial nanostructure layer 120 into the nanostructure channel layer 125) than the concentration of germanium in the nanostructure channel layer 125. The concentration of germanium in the silicon region 135 may be less than the concentration of germanium in the silicon germanium region 130, and less than the concentration of germanium in the sacrificial nanostructure layer 120. Thus, the concentration of germanium may increase from the nanostructure channel layer 125 to the sacrificial nanostructure layer 120 through the silicon region 135 and the silicon germanium region 130. In some implementations, the silicon region 135 is a region within the nanostructure channel layer 125.

One or more masking layers may be formed (e.g., using one or more deposition tools) on the layer stack 115. The masking layer(s) may include a hard mask (HM) layer 140, a capping layer 145, an oxide layer 150, and/or a nitride layer 155. Masking layer(s) may be used to perform a fin patterning operation to form fin structures in the semiconductor substrate 110.

As shown in FIG. 1B, the layer stack 115 and the semiconductor substrate 110 are etched to remove portions of the layer stack 115 and portions of the semiconductor substrate 110. This results in formation of fin structures 160 that extend above the semiconductor substrate 110. The fin structures 160 may extend in ay-direction in the semiconductor device 105 and may be arranged in an x-direction in the semiconductor device 105. A fin structure 160 includes a portion 165 of the layer stack 115 over and/or on a fin portion 170 above the semiconductor substrate 110. The fin structures 160 may be formed by patterning the one or more masking layers and etching the semiconductor substrate 110 based on a pattern formed in one or more of the masking layers. The one or more masking layers may be patterned using photolithography techniques, including double-patterning or multi-patterning techniques. An etch tool may be used to etch the semiconductor substrate 110 based on the pattern using a dry etch technique (e.g., reactive ion etching), a wet etch technique, and/or a combination thereof.

As further shown in FIG. 1B, some fin structures 160 may be formed to have different widths for different types of nanostructure transistors. As an example, a first subset of fin structures 160a may be formed for p-type nanostructure transistors (e.g., p-type metal oxide semiconductor (PMOS) nanostructure transistors), and a second subset of fin structures 160b may be formed for n-type nanostructure transistors (e.g., n-type metal oxide semiconductor (NMOS) nanostructure transistors). As another example, a first subset of fin structures 160a may be formed for nanostructure transistors that are configured to operate at lower voltages, and a second subset of fin structures 160b may be formed for nanostructure transistors that are configured to operate at higher voltages.

As shown in FIG. 1C, a liner 175 and STI regions 180 are formed between adjacent fin portions 170 of the fin structures 160. The liner 175 and the STI regions 180 may each include a dielectric material such as a silicon oxide (SiOₓ), a silicon nitride (SiₓN_{y}), a silicon oxynitride (SiON), fluoride-doped silicate glass (FSG), a low-k dielectric material, and/or another suitable insulating material.

A deposition tool may be used to conformally deposit the liner 175 (e.g., using ALD or another conformal deposition technique), and may deposit a dielectric layer (e.g., using CVD, PVD, a ALD, and/or another suitable deposition technique) on the liner 175 such that the dielectric layer fully fills in the spaces between the fin structures 160 and extends above the tops of the fin structures 160. A planarization tool may then be used to perform a planarization or polishing operation (e.g., a chemical mechanical planarization (CMP) operation) to planarize the dielectric layer such that the top surface of the dielectric layer is approximately co-planar with the top of the nitride layer 155. The nitride layer 155 functions as a CMP stop layer in the planarization operation. An etch tool may be used to then etch the dielectric layer to form the STI regions 180 such that the top surfaces of the STI region 180 are approximately co-planar with or below the bottom-most sacrificial nanostructure layer 120.

As indicated above, FIGS. 1A-1C are provided as an example. Other examples may differ from what is described with regard to FIGS. 1A-1C.

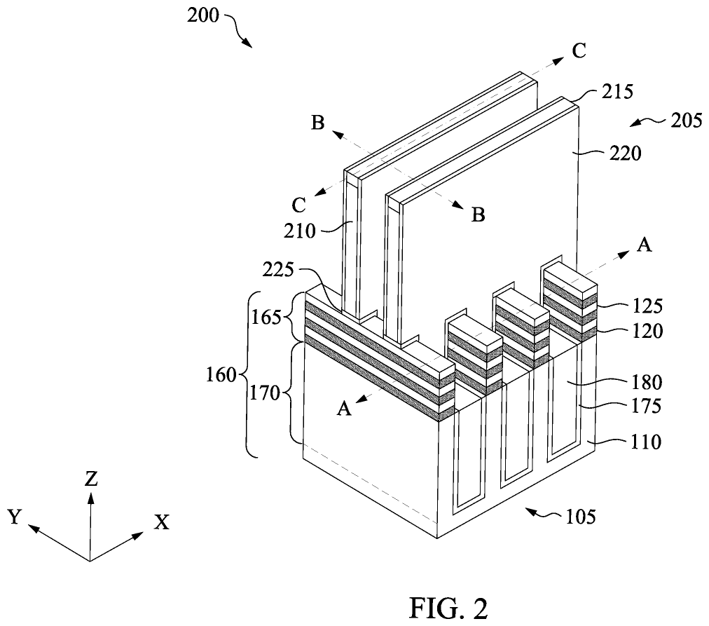

FIG. 2 is a diagram of an example implementation 200 of a dummy gate formation process described herein. The example implementation 200 includes an example of forming dummy gate structures 205 for nanostructure transistors of the semiconductor device 105. In some implementations, the operations described in connection with the example implementation 700 are performed after the processes described in connection with FIGS. 1A-1C.

FIG. 2 illustrates a perspective view of the semiconductor device 105 with the dummy gate structures 205 formed thereon. The dummy gate structures 205 (also referred to as dummy gate stacks or temporary gate structures) are formed over portions of the fin structures 160 and portions of the STI regions 180. The dummy gate structures 205 extend in the x-direction and are arranged in they-direction such that the dummy gate structures 205 are approximately perpendicular to the fin structures 160. The dummy gate structures 205 are sacrificial structures that are to be replaced by replacement gate structures or replacement gate stacks at a subsequent processing stage for the semiconductor device 105. The dummy gate structures 205 may also be used to define source/drain (S/D) recesses in which source/drain regions of the nanostructure transistors are formed in the fin structures 160.

A dummy gate structure 205 may include a gate electrode layer 210, a hard mask layer 215 over and/or on the gate electrode layer 210, and spacer layers 220 on opposing sides of the gate electrode layer 210, and a gate dielectric layer 225 under the gate electrode layer 210. The gate electrode layer 210 includes polycrystalline silicon (polysilicon or PO) or another material. The hard mask layer 215 includes one or more layers such as an oxide layer (e.g., a pad oxide layer that may include silicon dioxide (SiO₂) or another material) and a nitride layer (e.g., a pad nitride layer that may include a silicon nitride such as Si₃N₄ or another material) formed over the oxide layer. The spacer layers 220 include a silicon oxycarbide (SiOC), a nitrogen free SiOC, or another suitable material. The gate dielectric layer 225 may include a silicon oxide (e.g., SiOₓ such as SiO₂), a silicon nitride (e.g., SiₓN_{y} such as Si₃N₄), a high dielectric constant (high-k) dielectric material (e.g., a dielectric material having a dielectric constant greater than approximately 3.9) and/or another suitable material.

The layers of the dummy gate structures 205 may be formed using various semiconductor processing techniques such depositing the layers of the dummy gate structures 205, patterning the layers of the dummy gate structures 205 to define the dummy gate structures 205, and/or other semiconductor processing techniques.

FIG. 2 further illustrates reference cross-sections that are used in subsequent figures described herein. Cross-section A-A is in an x-z plane (referred to as a y-cut) across the fin structures 160 in the source/drain areas of the semiconductor device 105. Cross-section B-B is in ay-z plane (referred to as an x-cut) perpendicular to the cross-section A-A, and is across the dummy gate structures 205 and along an underlying fin structure 160. Cross-section C-C is in the x-z plane parallel to the cross-section A-A and perpendicular to the cross-section B-B, and is along a dummy gate structure 205. Subsequent figures refer to these reference cross-sections for clarity. In some figures, some reference numbers of components or features illustrated therein may be omitted to avoid obscuring other components or features for ease of depicting the figures.

As indicated above, FIG. 2 is provided as an example. Other examples may differ from what is described with regard to FIG. 2.

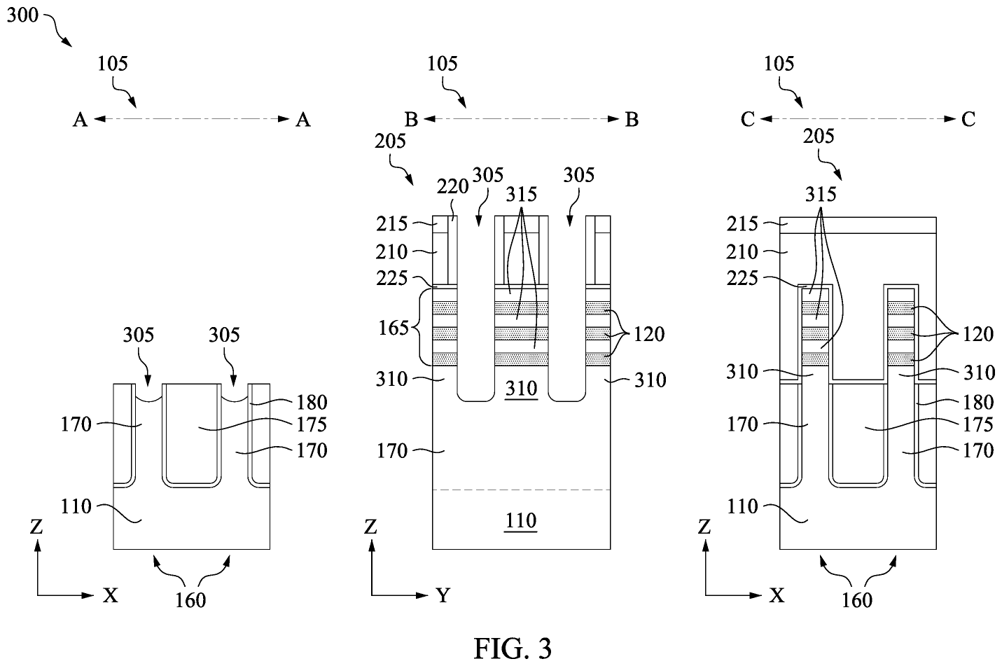

FIG. 3 is a diagrams of an example implementation 300 of a source/drain recess formation process described herein. The example implementation 300 includes an example of forming source/drain recesses 305 for source/drain regions of nanostructure transistors of the semiconductor device 105. FIG. 3 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 300 are performed after the processes described in connection with FIGS. 1A-2.

As shown in the cross-sectional plane A-A and cross-sectional plane B-B in FIG. 3, the source/drain recesses 305 are formed through portions 165 of a fin structure 160 in an etch operation. The source/drain recesses 305 are formed on opposing sides of a dummy gate structure 205. The etch operation may be performed using the etch tool and may be referred to a strained source/drain (SSD) etch operation. In some implementations, the etch operation includes the use of a plasma etch technique, a wet chemical etch technique, and/or another type of etch technique.

The source/drain recesses 305 also extend into a portion of the fin portion 170 of the fin structure 160. This results in formation of mesa regions 310 in the fin structure 160. The sidewalls of the portions of each source/drain recess 305 below the layer stack 115 correspond to sidewalls of mesa regions 310. A mesa region 310 (also referred to as pedestals) refers to a region of the fin portion 170 of the fin structure 160 on which nanostructure channels are defined from the nanostructure channel layers 125. The nanostructure channels 315 extend between adjacent source/drain recesses 305 and are located under the dummy gate structure 205 between the adjacent source/drain recesses 305.

The nanostructure channels 315 include silicon-based nanostructures (e.g., nanosheets or nanowires, among other examples) that function as the semiconductive channels of the nanostructure transistors of the semiconductor device 105. In some implementations, the nanostructure channels 315 may include silicon germanium (SiGe) or another silicon-based material. The nanostructure channels 315 are arranged in a direction (e.g., the z-direction) that is approximately perpendicular to the semiconductor substrate 110. In other words, the nanostructure channels 315 are vertically arranged or stacked above the semiconductor substrate 110.

As indicated above, FIG. 3 is provided as an example. Other examples may differ from what is described with regard to FIG. 3.

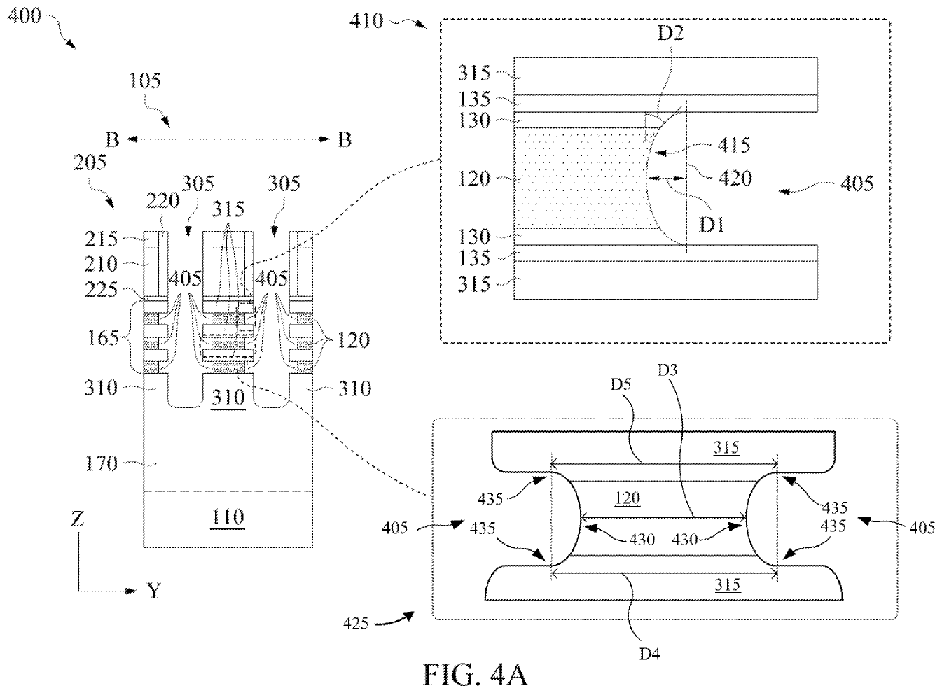

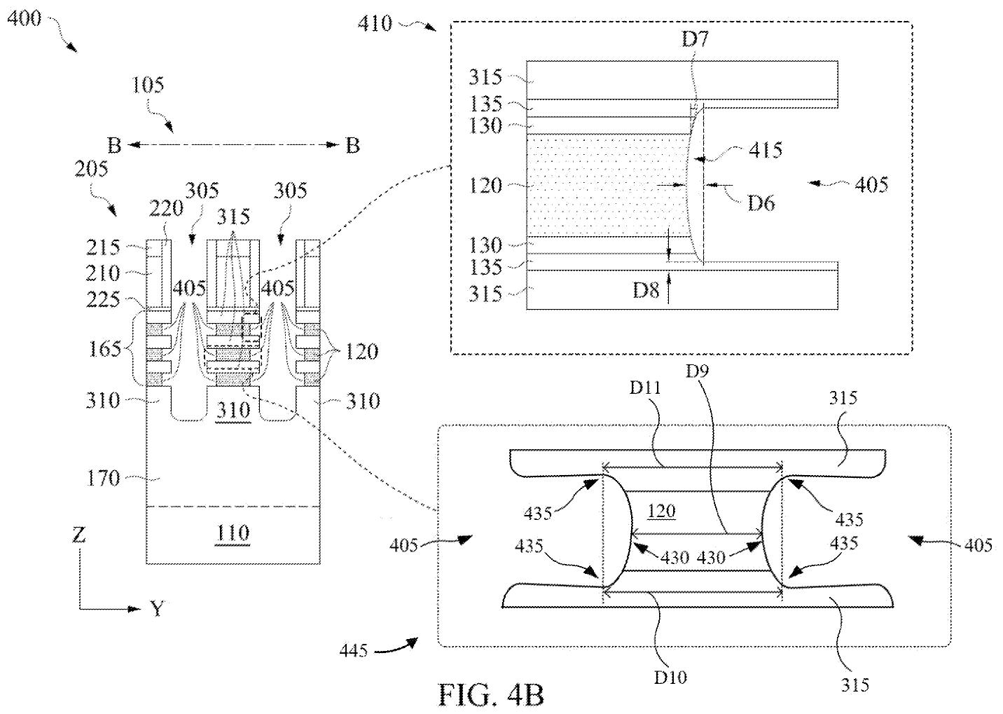

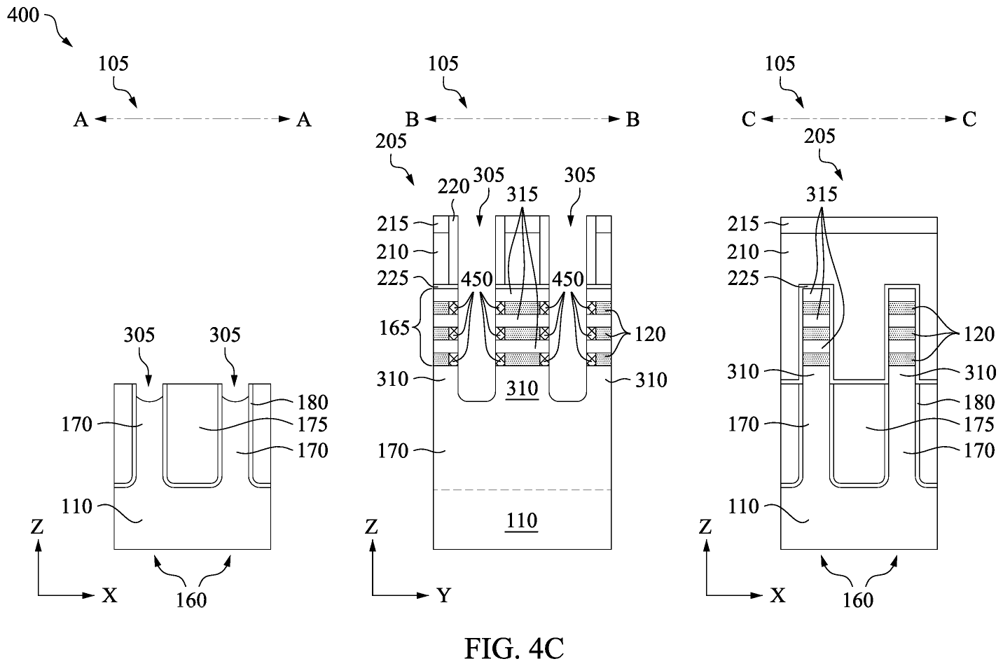

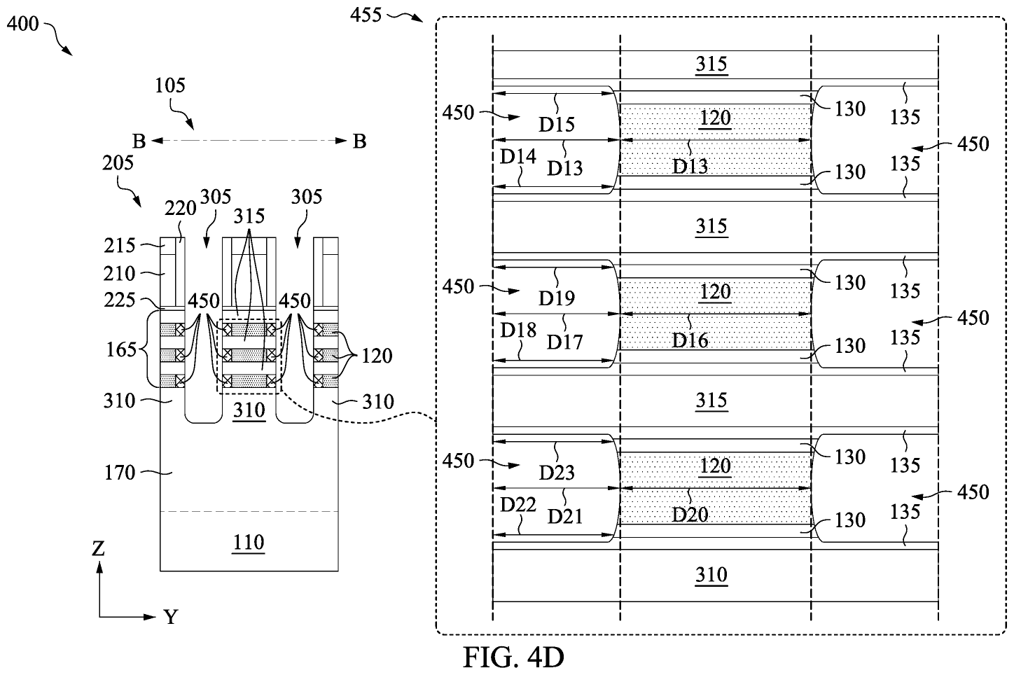

FIGS. 4A-4C are diagrams of an example implementation 400 of an inner spacer formation process described herein. The example implementation 400 includes an example of forming inner spacers between ends of the nanostructure channels 315 that are exposed in the source/drain recesses 305. FIGS. 4A-4C are each illustrated from one or more perspectives illustrated in FIG. 2, including the perspective of the cross-sectional plane A-A in FIG. 2, the perspective of the cross-sectional plane B-B in FIG. 2, and/or the perspective of the cross-sectional plane C-C in FIG. 2. In some implementations, the operations described in connection with the example implementation 400 are performed after the processes described in connection with FIGS. 1A-3.

As shown in the cross-sectional plane B-B in FIG. 4A, the ends of the sacrificial nanostructure layers 120 that are exposed in the source/drain recesses 305 are laterally etched (e.g., in the x-direction that is approximately parallel to a length of the sacrificial nanostructure layers 120) in one or more first etch operations, thereby forming cavities 405 between the ends of the sacrificial nanostructure channels 120 that are exposed in the source/drain recesses 305. In particular, an etch tool may be use to laterally etch the ends of the sacrificial nanostructure layers 120 under the dummy gate structures 205 through the source/drain recesses 305 to form the cavities 405 between ends of the nanostructure channels 315.

In implementations where the sacrificial nanostructure layers 120 are silicon germanium (SiGe) and the nanostructure channels 315 are silicon (Si), the sacrificial nanostructure layers 120 are etched in the one or more first etch operations using a wet etchant such as a mixed solution including hydrogen peroxide (H₂O₂), acetic acid (CH₃COOH), and/or hydrogen fluoride (HF), followed by cleaning with water (H₂O). The mixed solution and the water may be provided into the source/drain recesses 305 to etch the sacrificial nanostructure layers 120 in the source/drain recesses 305. In some implementations, the etching by the mixed solution and cleaning by water is repeated for a plurality of cycles to form the cavities 405.

As shown in a detailed view 410 in FIG. 4A, a cavity 405 may have a curved or arc-shaped inner surface 415. In particular, the inner surface 415 may be concave such that a center point of the inner surface 415 extends inward into the cavity 405 from a base 420 corresponding to top and bottom ends of the inner surface 415. The base 420 corresponds to an arc base of the arc of the inner surface 415. The cavity has a dimension D1 after the one or more first etch operations corresponding to a first distance between an approximate center point of the arc of the inner surface 415 and an approximate center point of the base 420 of the arc. The inner surface 415 has a first radius of curvature after the one or more first etch operations. The first radius of curvature R corresponds to a reciprocal of the curvature (κ) of the inner surface 415 (e.g., R=1/κ).

The top and bottom corners of the cavity 405 correspond to the transitions between inner surface 415 and the sidewalls of the cavity 405, where the sidewalls of the cavity 405 are the top and bottom surfaces of the cavity 405. The cavity has a dimension D2 after the one or more first etch operations corresponding to a first angle of the corners of the cavity 405 (e.g., a first angle of the transition between the inner surface 415 and a z-direction plane in the semiconductor device 105). In some implementations, the dimension D2 is included in a range of approximately 40 degrees to approximately 45 degrees. However, other values for the range are within the scope of the present disclosure.

As shown in another detailed view 425 in FIG. 4A, a distance (indicated in FIG. 4A as dimension D3) between approximate center points 430 of cavities 405 that are formed in opposing ends of a sacrificial nanostructure layer 120 in the one or more first etch operations is less than a distance (indicated in FIG. 4A as a dimension D4) between end points 435 at the bottoms of the cavities 405 after the one or more first etch operations, and is less than a distance (indicated in FIG. 4A as a dimension D5) between end points 435 at the tops of the cavities 405 after the one or more first etch operations. Rounding of the inner surfaces 415 of the cavities 405 may correspond to one half of an average of the difference between the dimension D5 and the dimension D3, and the difference between the dimension D4 and the dimension D3 (e.g., Rounding=[AVG (D5−D3) & (D4−D3)]/2).

As shown in the cross-sectional plane B-B in FIG. 4B, one or more second etch operations are performed (e.g., using an etch tool) to modify a cross-sectional profile of the inner surfaces 415 of the cavities 405. In particular, the one or more second etch operations may be performed to laterally etch the cavities 405 to trim the corners of the cavities 405, which reduces corner rounding in the cavities 405. In other words, the one or more second etch operations are performed to flatten the inner surfaces 415 (e.g., flatten the cross-sectional curvature of the inner surfaces 415) of the cavities 405.

As shown in a detailed view 440 in FIG. 4B, the one or more second etch operations may include trimming (e.g., removing portions of) the silicon germanium regions 130 at the tops and bottoms of a cavity 405, and trimming (e.g., removing portions of) the silicon regions 135 at the tops and bottoms of the cavity 405, to increase the orthogonality in the top and bottom corners of the cavity 405. An etch technique selectively etches the silicon germanium regions 130 and the silicon regions 135 in the cavity 405, with minimal to no etching of the sacrificial nanostructure layer 120 and the ends of nanostructure channels 315 in the cavity 405. For example, the one or more second etch operations may include performing an etch operation using a gas-based etchant that includes a combination of fluorine (F₂) and ammonia (NH₃). The combination of fluorine (F₂) and ammonia (NH₃) may be used to form a protective layer on the inner surface 415 of the cavity 405 (corresponding to the end of the sacrificial nanostructure layer 120 exposed in the cavity 405) that inhibits etching of the portions of the inner surface 415 corresponding to the sacrificial nanostructure layer 120, while the combination of fluorine (F₂) and ammonia (NH₃) is used to etch the exposed surfaces of the silicon germanium regions 130 and the silicon regions 135 in the cavity 405.

The combination of fluorine (F₂) and ammonia (NH₃) may selectively form the protective layer on the sacrificial nanostructure layer 120 because of the high germanium content in the sacrificial nanostructure layer 120, and may selectively etch the silicon germanium regions 130 and the silicon regions 135 because of the high silicon content in the silicon germanium regions 130 and the silicon regions 135. The protective layer is formed on the surface of the sacrificial nanostructure layer 120 in the cavity 405 as a result of a reaction between the germanium in sacrificial nanostructure layer 120 and the fluorine (F₂) and ammonia (NH₃) in the gas-based etchant. The reaction may include:

$$SiGe + 4 {F}_{2} + {NH}_{3} \to {SiF}_{4} + {GeF}_{4} + {NH}_{3} \to {GeF}_{4} + 2 HF + 2 {NH}_{3} \to {( {NH}_{4} )}_{2} {GeF}_{6} ,$$

where the fluorine (F₂) and the ammonia (NH₃) react with the germanium (Ge) to form ammonium fluorogermanate ((NH₄)₂GeF₆) on the exposed surface of the sacrificial nanostructure layer 120 in the cavity 405. The ammonium fluorogermanate (AFG) protects (or reduces an etch rate for) the sacrificial nanostructure layer 120 from being etched in the one or more second etch operations.

The fluorine (F₂) and ammonia (NH₃) in the gas-based etchant may react with the silicon (Si) in the silicon germanium regions 130 and with the silicon in the silicon regions 135 to reduce corner rounding of the cavity 405 (e.g., while the protective layer protects the sacrificial nanostructure layer 120) in the one or more second etch operations. The reaction may include:

$$Si + 2 {F}_{2} + {NH}_{3} \to {SiF}_{4} ↑ + {NH}_{3} \to {SiF}_{4} + {F}_{2} + 4 {NH}_{3} \to {( {NH}_{4} )}_{2} {SiF}_{6} + {NH}_{3} ,$$

where the fluorine (F₂) and the ammonia (NH₃) react with the silicon (Si) to form ammonium fluorosilicate ((NH₄)₂SiF₆) on the exposed surface of the silicon germanium regions 130 and on the exposed surfaces of the silicon regions 135 in the cavity 405. The ammonium fluorosilicate (AFS) is then etched by the ammonia (NH₃) to remove material of the silicon germanium regions 130 and material of the silicon regions 135 from the cavity 405.

In some implementations, the fluorine (F₂) and the ammonia (NH₃) may be pre-mixed in a gas-supply system of an etch tool that is used to perform the one or more second etch operations. The mixture of the fluorine (F₂) and the ammonia (NH₃) may then be provided into a processing chamber of the etch tool, in which the semiconductor device 105 is positioned, to perform the one or more second etch operations. In some implementations, the fluorine (F₂) and the ammonia (NH₃) are provided into the processing chamber as separate gas flows, and the fluorine (F₂) and the ammonia (NH₃) mix and react within the processing chamber to perform the one or more second etch operations. For example, the gas flow of the fluorine (F₂) may be provided into the processing chamber first, to perform a fluorine treatment, the gas flow of the fluorine (F₂) may be stopped, and then the gas flow of the ammonia (NH₃) may then be provided into a chamber. In some implementations, pre-mixing the fluorine (F₂) and the ammonia (NH₃) may result in a faster etch rate for the silicon germanium regions 130 and the silicon regions 135 with some etching of the sacrificial nanostructure layer 120, whereas providing separate gas flows of the fluorine (F₂) and the ammonia (NH₃) may result in a slower and more controlled etch rate for the silicon germanium regions 130 and the silicon regions 135.

In some implementations, a flow rate of the gas flow of the fluorine (F₂) may be included in a range of approximately 10 standard cubic centimeters per minute (SCCM) to approximately 100 SCCM. Less than 10 SCCM may result in insufficient flattening of the inner surfaces 415 of the cavities 405, whereas greater than 100 SCCM may result in over etching into the silicon germanium regions 130 and the silicon regions 135. Providing the flowrate in the range of approximately 10 SCCM to approximately 100 SCCM may result in flattening of the inner surfaces 415 of the cavities 405 with minimal over etching into the silicon germanium regions 130 and the silicon regions 135. However, other values and ranges for the flow rate of the fluorine (F₂) are within the scope of the present disclosure.

In some implementations, a time duration for providing the gas flow of the fluorine (F₂) may be included in a range of approximately 30 seconds to approximately 360 seconds. Less than 30 seconds may result in insufficient flattening of the inner surfaces 415 of the cavities 405, whereas greater than 360 seconds may result in over etching into the silicon germanium regions 130 and the silicon regions 135. Providing the gas flow for a time duration that is in the range of approximately 30 seconds to approximately 360 seconds may result in flattening of the inner surfaces 415 of the cavities 405 with minimal over etching into the silicon germanium regions 130 and the silicon regions 135. However, other values and ranges for the time duration for providing the gas flow of the fluorine (F₂) are within the scope of the present disclosure.

In some implementations, a flow rate of the gas flow of the ammonia (NH₃) may be included in a range of approximately 50 SCCM to approximately 500 SCCM. Less than 50 SCCM may result in insufficient flattening of the inner surfaces 415 of the cavities 405, whereas greater than 500 SCCM may result in over etching into the silicon germanium regions 130 and the silicon regions 135. Providing the flowrate in the range of approximately 50 SCCM to approximately 500 SCCM may result in flattening of the inner surfaces 415 of the cavities 405 with minimal over etching into the silicon germanium regions 130 and the silicon regions 135. However, other values and ranges for the flow rate of the ammonia (NH₃) are within the scope of the present disclosure.

In some implementations, a time duration for providing the gas flow of the ammonia (NH₃) may be included in a range of approximately 30 seconds to approximately 360 seconds. Less than 30 seconds may result in insufficient flattening of the inner surfaces 415 of the cavities 405, whereas greater than 360 seconds may result in over etching into the silicon germanium regions 130 and the silicon regions 135. Providing the gas flow for a time duration that is in the range of approximately 30 seconds to approximately 360 seconds may result in flattening of the inner surfaces 415 of the cavities 405 with minimal over etching into the silicon germanium regions 130 and the silicon regions 135. However, other values and ranges for the time duration for providing the gas flow of the ammonia (NH₃) are within the scope of the present disclosure.

In some implementations, a cyclic etch technique is used to perform the one or more second etch operations, where a plurality of etch cycles are performed to etch the silicon germanium regions 130 and the silicon regions 135 in the cavities 405. Each etch cycle may include etching the silicon germanium regions 130 and the silicon regions 135 using the gas-based etchant, followed by removing etch byproducts (e.g., from the processing chamber) resulting from the etching the silicon germanium regions 130 and the silicon regions 135. In some implementations, the quantity of etch cycles is included in a range of approximately 2 etch cycles to approximately 10 etch cycles. Less than 2 etch cycles may result in insufficient flattening of the inner surfaces 415 of the cavities 405, whereas greater than 10 etch cycles may result in over etching into the silicon germanium regions 130 and the silicon regions 135. Performing 2 to 10 etch cycles may result in flattening of the inner surfaces 415 of the cavities 405 with minimal over etching into the silicon germanium regions 130 and the silicon regions 135. However, other values and ranges for the quantity of etch cycles are within the scope of the present disclosure.

While examples of the one or more second etch operations described herein include the use of a gas-based etchant that includes fluorine (F₂) and ammonia (NH₃), other gas-based etchants and other types of etchants (e.g., wet etchants, plasma-based etchants) may be used to perform the one or more second etch operations.

As shown in the detailed view 440 in FIG. 4B, a cavity 405 has a dimension D6 after the one or more second etch operations corresponding to a second distance between an approximate center point of the arc of the inner surface 415 and an approximate center point of the base 420 of the arc. The second distance after the one or more second etch operations is less than the first distance (the dimension D1) after the one or more first etch operations as a result of the reduced cross-sectional curvature of the inner surface 415 that is achieved by the one or more second etch operations. The inner surface 415 has a second radius of curvature after the one or more first second operations. The second radius of curvature R is greater than the first radius of curvature of the inner surface 415 after the one or more first etch operations because of the reduced cross-sectional curvature (K) of the inner surface 415 that is achieved by the one or more second etch operations.

As further shown in the detailed view 440 in FIG. 4B, the cavity 405 has a dimension D7 after the one or more second etch operations corresponding to a second angle of the corners of the cavity 405 (e.g., a second angle of the transition between the inner surface 415 and a z-direction plane in the semiconductor device 105). The second angle of the corners of the cavity 405 after the one or more second etch operations is less than the first angle of the corners of the cavity (the dimension D2) after the one or more first etch operations as a result of the reduced cross-sectional curvature of the inner surface 415 that is achieved by the one or more second etch operations. In some implementations, the dimension D6 is less than approximately 10 degrees. However, other values for the dimension D6 are within the scope of the present disclosure.

As shown in another detailed view 445 in FIG. 4B, a distance (indicated in FIG. 4B as dimension D9) between approximate center points 430 of cavities 405 in opposing ends of a sacrificial nanostructure layer 120 after the one or more second etch operations is less than a distance (indicated in FIG. 4B as a dimension D10) between end points 435 at the bottoms of the cavities 405 after the one or more second etch operations, and is less than a distance (indicated in FIG. 4B as a dimension D11) between end points 435 at the tops of the cavities 405 after the one or more second etch operations. Moreover, the difference between the dimension D10 and the dimension D9, and the difference between the dimension D11 and the dimension D9, are less than the difference between the dimension D4 and the dimension D3, and are less than the difference between the dimension D5 and the dimension D3. Thus, the rounding of the inner surfaces 415 of the cavities 405 after the one or more second etch operations is less than the rounding of the inner surfaces 415 of the cavities prior to the one or more second etch operations.

As shown in the cross-sectional plane A-A and in the cross-sectional plane B-B in FIG. 4C, inner spacers 450 are formed in the cavities 405 between the ends of vertically adjacent nanostructure channels 315 in the source/drain recesses 305. The inner spacers 450 are included to reduce parasitic capacitance in the nanostructure transistors and to protect source/drain regions (that are subsequently formed in the source/drain recesses 305) from being etched in a nanosheet release operation to remove the sacrificial nanostructure layers 120 between the nanostructure channels 315. As indicated above, the techniques described in connection with FIGS. 4A-4C that are used to form the cavities 405 in which the inner spacers 450 are formed enable a high uniformity in the lateral thickness of the inner spacers 450 to be achieved, which reduces the likelihood of etching through the inner spacers 450 and into the source/drain regions relative to other cavity formation techniques. The inner spacers 450 include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

To form the inner spacers 450, a deposition tool may be used to deposit a layer of dielectric material in the cavities 405 and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 450 in the cavities 405. In some implementations, the etch operation may result in the surfaces of the inner spacers 450 facing the source/drain recesses 305 being curved or recessed. In some implementations, the surfaces of the inner spacers 450 facing the source/drain recesses 305 are approximately flat such that the surfaces of the inner spacers 450 and the surfaces of the ends of the nanostructure channels 315 are approximately even and flush.

As shown in a detailed view 455 of the cross-sectional plane B-B in FIG. 4D, the sacrificial nanostructure layers 120 and/or the inner spacers 450 may have one or more dimensions as a result of the multiple-etch process described in connection with FIGS. 4A and 4B to form the cavities 405 in which the inner spacers 450 are formed. A sacrificial nanostructure layer 120 between a top-most nanostructure channel 315 and a middle nanostructure channel 315 under the top-most nanostructure channel 315 may have a cross-sectional width in they-direction corresponding to a dimension D12 (at an approximate center of the portion of the sacrificial nanostructure layer 120 between adjacent inner spacers 450). In some implementations, the dimension D12 is included in a range of approximately 12 nanometers to approximately 18 nanometers. However, other values for the range are within the scope of the present disclosure. An inner spacer 450 adjacent to the sacrificial nanostructure layer 120 may have cross-sectional widths in the y-direction corresponding to a dimension D13 at an approximate center of the inner spacer 450, a dimension D14 at a bottom of the inner spacer 450, and a dimension D15 at atop of the inner spacer 450. In some implementations, the difference between the dimension D13 and the dimension D14, and the difference between the dimension D13 and the dimension D15, may each be included in a range of approximately 0.5 nanometers to approximately 1.5 nanometers such that a high uniformity of lateral thickness may be achieved for the inner spacer 450. This enables a low likelihood of etching through the inner spacer 450 (e.g., at the top or bottom of the inner spacer 450) to be achieved. However, other values and other ranges are within the scope of the present disclosure.

A sacrificial nanostructure layer 120 between the middle nanostructure channel 315 and a bottom-most nanostructure channel 315 under the middle nanostructure channel 315 may have a cross-sectional width in they-direction corresponding to a dimension D16 (at an approximate center of the portion of the sacrificial nanostructure layer 120 between adjacent inner spacers 450). In some implementations, the dimension D16 is included in a range of approximately 12 nanometers to approximately 18 nanometers. However, other values for the range are within the scope of the present disclosure. An inner spacer 450 adjacent to the sacrificial nanostructure layer 120 may have cross-sectional widths in the y-direction corresponding to a dimension D17 at an approximate center of the inner spacer 450, a dimension D18 at a bottom of the inner spacer 450, and a dimension D19 at a top of the inner spacer 450. In some implementations, the difference between the dimension D17 and the dimension D18, and the difference between the dimension D17 and the dimension D18, may each be included in a range of approximately 0.5 nanometers to approximately 1.5 nanometers, such that a high uniformity of lateral thickness may be achieved for the inner spacer 450. This enables a low likelihood of etching through the inner spacer 450 (e.g., at the top or bottom of the inner spacer 450) to be achieved. However, other values and other ranges are within the scope of the present disclosure.

In some implementations, a difference between the dimension D17 and the dimension D13 is less than approximately 6 nanometers. However, other values for the range are within the scope of the present disclosure. In some implementations, a difference between the dimension D18 and the dimension D14 is less than approximately 6 nanometers. However, other values for the range are within the scope of the present disclosure. In some implementations, a difference between the dimension D19 and the dimension D15 is less than approximately 6 nanometers. However, other values for the range are within the scope of the present disclosure.

A sacrificial nanostructure layer 120 between the bottom-most nanostructure channel 315 and a mesa region 310 under the bottom-most nanostructure channel 315 may have a cross-sectional width in the y-direction corresponding to a dimension D20 (at an approximate center of the portion of the sacrificial nanostructure layer 120 between adjacent inner spacers 450). In some implementations, the dimension D20 is included in a range of approximately 12 nanometers to approximately 18 nanometers. However, other values for the range are within the scope of the present disclosure. An inner spacer 450 adjacent to the sacrificial nanostructure layer 120 may have cross-sectional widths in they-direction corresponding to a dimension D21 at an approximate center of the inner spacer 450, a dimension D22 at a bottom of the inner spacer 450, and a dimension D23 at a top of the inner spacer 450. In some implementations, the difference between the dimension D21 and the dimension D22, and the difference between the dimension D21 and the dimension D23, may each be included in a range of approximately 0.5 nanometers to approximately 1.5 nanometers, such that a high uniformity of lateral thickness may be achieved for the inner spacer 450. This enables a low likelihood of etching through the inner spacer 450 (e.g., at the top or bottom of the inner spacer 450) to be achieved. However, other values and other ranges are within the scope of the present disclosure.

In some implementations, a difference between the dimension D21 and the dimension D13 is less than approximately 6 nanometers. However, other values for the range are within the scope of the present disclosure. In some implementations, a difference between the dimension D22 and the dimension D14 is less than approximately 6 nanometers. However, other values for the range are within the scope of the present disclosure. In some implementations, a difference between the dimension D23 and the dimension D15 is less than approximately 6 nanometers. However, other values for the range are within the scope of the present disclosure.

In some implementations, a difference between the dimension D21 and the dimension D17 is less than approximately 6 nanometers. However, other values for the range are within the scope of the present disclosure. In some implementations, a difference between the dimension D22 and the dimension D18 is less than approximately 6 nanometers. However, other values for the range are within the scope of the present disclosure. In some implementations, a difference between the dimension D23 and the dimension D19 is less than approximately 6 nanometers. However, other values for the range are within the scope of the present disclosure.

As indicated above, FIGS. 4A-4D are provided as an example. Other examples may differ from what is described with regard to FIGS. 4A-4D.

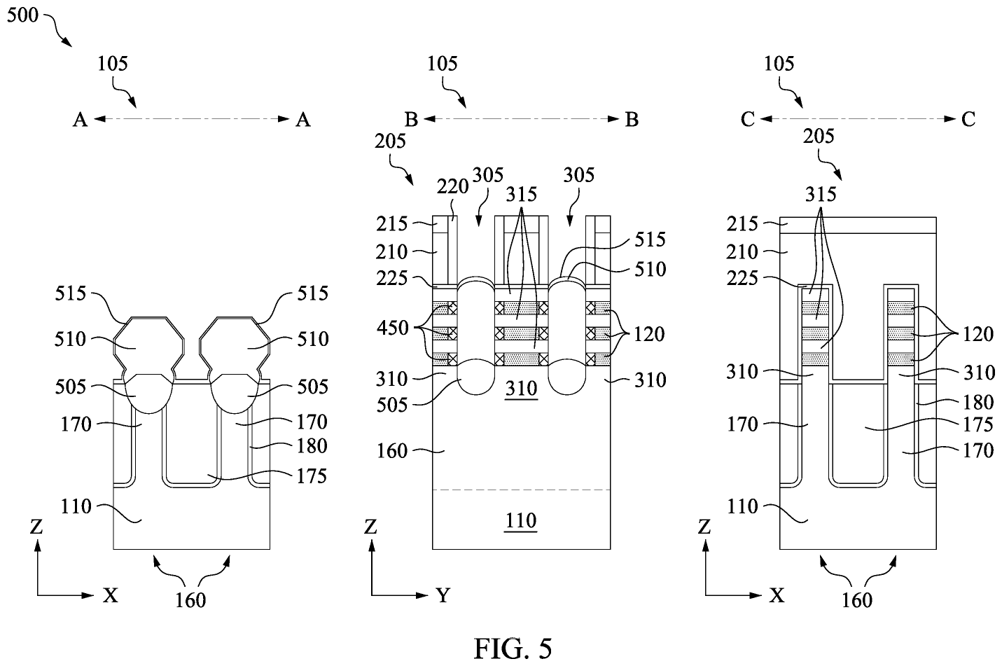

FIG. 5 is a diagram of an example implementation 500 of a source/drain region formation process described herein. The example implementation 500 includes an example of forming the source/drain regions of the nanostructure transistors of the semiconductor device 105. FIG. 5 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-4D.

As shown in the cross-sectional plane A-A and the cross-sectional plane B-B in FIG. 5, the source/drain recesses 305 are filled with one or more layers to form the source/drain regions in the source/drain recesses 305. For example, a deposition tool may be used to deposit a buffer region 505 at the bottom of the source/drain recess 305, and a deposition tool may deposit a source/drain region 510 on the buffer region 505 in the source/drain recess 305. In some implementations, a deposition tool is used to deposit a capping layer 515 on the source/drain regions 510 in the source/drain recess 305.

A buffer region 505 may include silicon (Si), silicon doped with boron (Si:B) or another dopant, and/or another material. A buffer region 505 may be included between a source/drain region 510 and the mesa regions 310 adjacent to the buffer region 505 to reduce, minimize, and/or prevent dopant migration and/or current leakage from the source/drain region 510 into the adjacent mesa region 310, which might otherwise cause short channel effects in the semiconductor device 105. Accordingly, the buffer region 505 may increase the performance of the semiconductor device 105 and/or increase yield of the semiconductor device 105.

“Source/drain region” may refer to a source or a drain, individually or collectively dependent upon the context. Source/drain regions 510 may be included on opposing sides of a dummy gate structure 205 such that the nanostructure channels 315 under the dummy gate structure 205 extend between, and are electrically coupled with, source/drain regions 510. The source/drain regions 510 each include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the semiconductor device 105 may include p-type metal-oxide semiconductor (PMOS) nanostructure transistors that include p-type source/drain regions 510, n-type metal-oxide semiconductor (NMOS) nanostructure transistors that include n-type source/drain regions 510, and/or other types of nanostructure transistors.

One or more layers of a source/drain region 510 may be epitaxially grown, deposited (e.g., using CVD, PVD, ALD), and/or may be formed using one or more other deposition techniques. For example, a deposition tool may epitaxially grow a first layer of a source/drain region 510 (referred to as an L1) over an associated buffer region 505 (which may be referred to as an L0), and may epitaxially grow a second layer of the source/drain region 510 (referred to as an L2, an L2-1, and/or an L2-2) over the first layer. The first layer may include a lightly doped silicon (e.g., doped with boron (B), phosphorous (P), and/or another dopant), and may be included as a shielding layer to reduce short channel effects in the semiconductor device 105 and to reduce dopant extrusion or migration into the nanostructure channels 315. The second layer may include a highly doped silicon or highly doped silicon germanium. The second layer may be included to provide a compressive stress in the source/drain regions 510 to reduce boron loss.

A capping layer 515 may include silicon, silicon germanium, doped silicon, doped silicon germanium, and/or another material. The capping layer 515 may be included to reduce dopant diffusion and to protect an underlying source/drain region 510 in semiconductor processing operations for the semiconductor device 105 prior to contact formation. Moreover, the capping layer 515 may contribute to metal-semiconductor (e.g., silicide) alloy formation.

As indicated above, FIG. 5 is provided as an example. Other examples may differ from what is described with regard to FIG. 5.

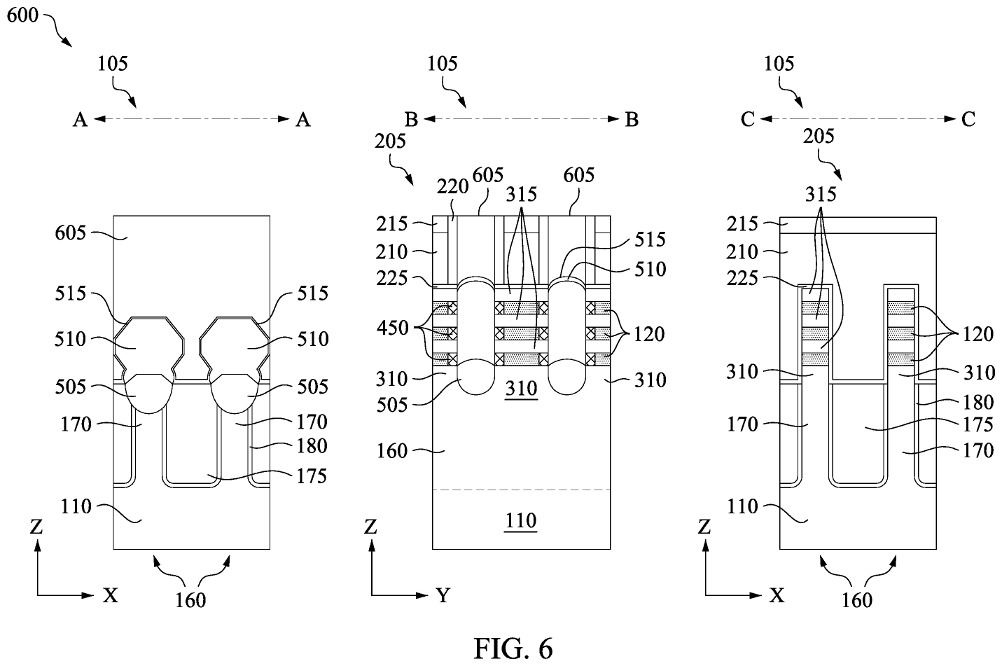

FIG. 6 is a diagram of an example implementation 600 of an interlayer dielectric (ILD) formation process described herein. FIG. 6 is illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 500 are performed after the processes described in connection with FIGS. 1A-5.

As shown in the cross-sectional plane A-A and the cross-sectional plane B-B in FIG. 6, a dielectric layer 605 is formed over the source/drain regions 510. The dielectric layer 605 (which may be referred to as an ILD layer) fills in areas between the dummy gate structures 205. The dielectric layer 605 is formed to reduce the likelihood of and/or prevent damage to the source/drain regions 510 during a replacement gate process to replace the dummy gate structures 205. The dielectric layer 605 may be referred to as an ILD zero (ILD0) layer or another ILD layer.

In some implementations, a contact etch stop layer (CESL) is conformally deposited (e.g., by a deposition tool) over the source/drain regions 510 prior to formation of the dielectric layer 605. Alternatively, the capping layer 515 may be a CESL. The dielectric layer 605 is then formed on the CESL. The CESL may provide a mechanism to stop an etch process when forming contacts or vias for the source/drain regions 510. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As indicated above, FIG. 6 is provided as an example. Other examples may differ from what is described with regard to FIG. 6.

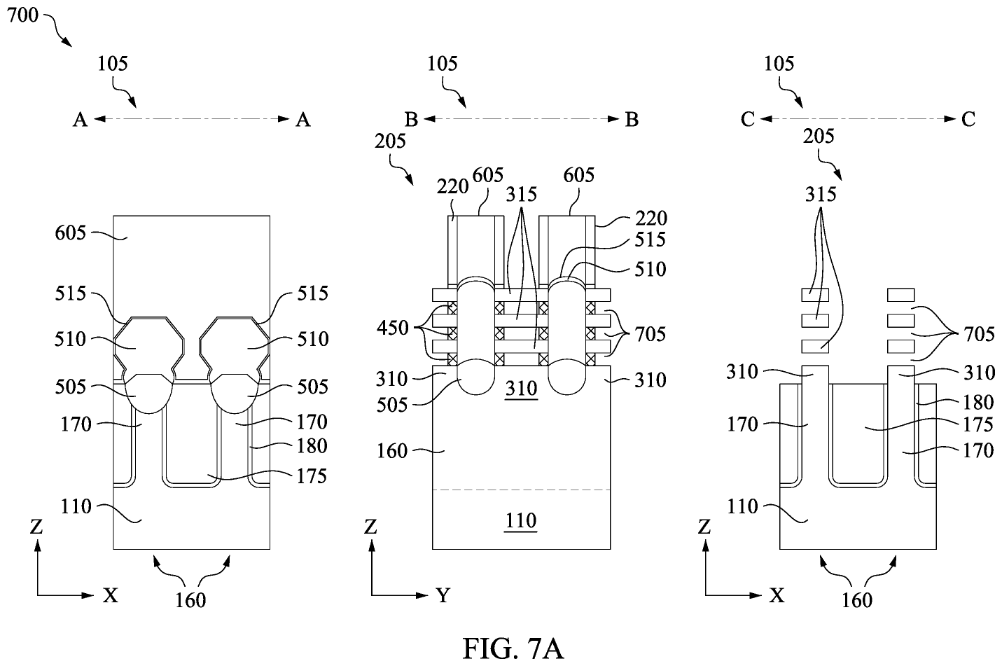

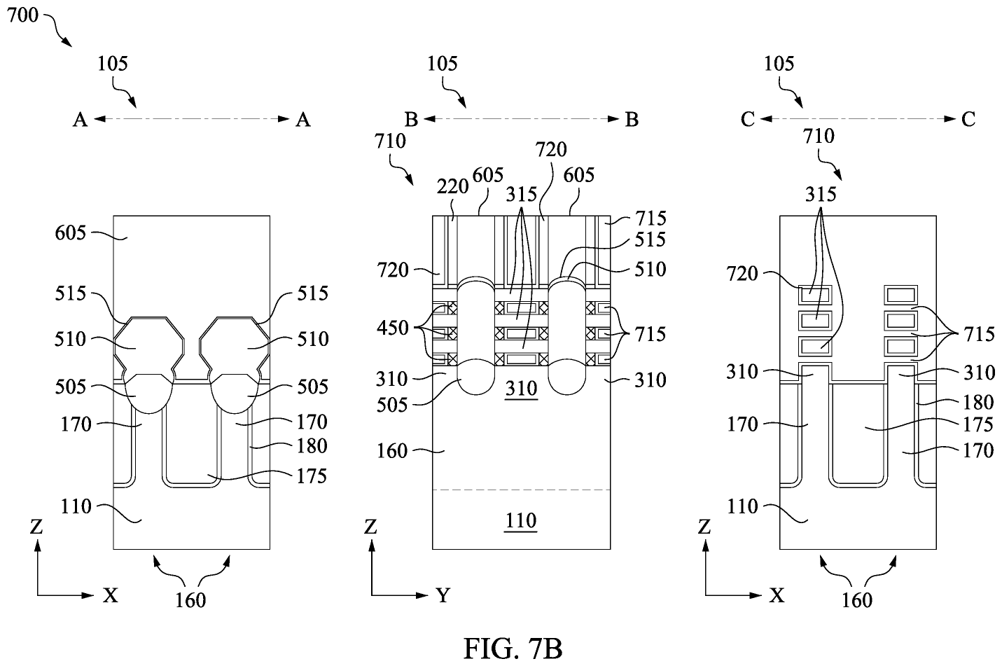

FIGS. 7A and 7B are diagrams of an example implementation 700 of a replacement gate (RPG) process described herein. The example implementation 700 includes an example of a replacement gate process for replacing the dummy gate structures 205 with high-k/metal gate structures (e.g., the replacement gate structures) for the nanostructure transistors of the semiconductor device 105. FIGS. 7A and 7B are each illustrated from a plurality of perspectives illustrated in FIG. 2, including the perspective of the cross-sectional plane A-A in FIG. 2, the perspective of the cross-sectional plane B-B in FIG. 2, and the perspective of the cross-sectional plane C-C in FIG. 2. In some implementations, the operations described in connection with the example implementation 700 are performed after the operations described in connection with FIGS. 1A-6.

As shown in the cross-sectional plane B-B and the cross-sectional plane C-C in FIG. 7A, the replacement gate process includes a dummy gate removal operation. The dummy gate removal operation includes removing the dummy gate structures 205 from the semiconductor device 105. The removal of the dummy gate structures 205 leaves behind openings (or recesses) between the dielectric layer 605, and provides access to the underlying sacrificial nanostructure layers 120. The dummy gate structures 205 may be removed in one or more etch operations. Such etch operations may include a plasma etch technique, a wet chemical etch technique, and/or another type of etch technique.

As further shown FIG. 7A, the replacement gate process includes a nanostructure release operation (e.g., an SiGe release operation). The nanostructure release operation is performed to remove the sacrificial nanostructure layers 120 (e.g., the silicon germanium layers). This results in openings 705 between the nanostructures channels 315 (e.g., the areas around the nanostructure channels 315). The sacrificial nanostructure layers 120 may be removed through the spaces that were previously occupied by the dummy gate structures 205. The nanostructure release operation may include the use of an etch tool to perform an etch operation to remove the sacrificial nanostructure layers 120 based on a difference in etch selectivity between the material of the sacrificial nanostructure layers 120 and the material of the nanostructure channels 315, and between the material of the sacrificial nanostructure layers 120 and the material of the inner spacers 450.

The inner spacers 450 may function as etch stop layers in the etch operation to protect the source/drain regions 510 from being etched. As indicated above, the techniques described in connection with FIGS. 4A-4C that are used to form the cavities 405 in which the inner spacers 450 are formed enable a high uniformity in the lateral thickness of the inner spacers 450 to be achieved, which reduces the likelihood of etching through the inner spacers 450 and into the source/drain regions 510, relative to other cavity formation techniques.

As shown in the cross-sectional plan B-B and the cross-sectional plane C-C in FIG. 7B, the replacement gate operation includes forming gate structures (e.g., replacement gate structures) 710 in the openings 705 between the source/drain regions 510 and between the inner spacers 450. In particular, the gate structures 710 fill the areas between and around the nanostructure channels 315 that were previously occupied by the sacrificial nanostructure layers 120 such that the gate structures 710 fully wrap around the nanostructure channels 315 and surround the nanostructure channels 315. This increases control of the nanostructure channel 315, increases drive current for the nanostructure transistor(s) of the semiconductor device 105, and/or reduces short channel effects (SCEs) for the nanostructure transistor(s) of the semiconductor device 105, among other examples. The gate structures 710 may also fill in the spaces that were previously occupied by the dummy gate structures 205. Portions of a gate structure 710 are formed in between pairs of nanostructure channels 315 in an alternating vertical arrangement. In other words, the semiconductor device 105 includes one or more vertical stacks of alternating nanostructure channels 315 and portions of a gate structure 710, as shown in FIG. 7B.

The gate structures 710 may each include a metal gate electrode 715. A metal gate electrode 715 may include one or more metal materials such as tungsten (W), cobalt (Co), ruthenium (Ru), and/or titanium (Ti), among other examples. Additionally and/or alternatively, the gate structures 710 may each include one or more work function metal layers for tuning the work function of the metal gate electrode 715.

A conformal high-k dielectric liners 720 of the gate structures 710 may be deposited onto the nanostructure channels 315 and on sidewalls of the inner spacers 450 prior to formation of the gate electrodes 715. The gate structures 710 may each include additional layers such as an interfacial layer, an adhesion layer, and/or a capping layer, among other examples. The high-k dielectric layers 720 each include one or more high-k dielectric materials, such as a silicon nitride (SiₓN_{y}), a hafnium oxide (HfOₓ), a lanthanum oxide (LaOₓ), and/or another suitable high-k dielectric material.

Some source/drain regions 510 and gate structures 710 may be shared between two or more nanoscale transistors of the semiconductor device 105. In these implementations, one or more source/drain regions 510 and a gate structure 710 may be connected or coupled to a plurality of nanostructure channels 315, as shown in the example in FIG. 7B. This enables the plurality of nanostructure channels 315 to be controlled by a single gate structure 710 and a pair of source/drain regions 510.

As indicated above, FIGS. 7A and 7B are provided as an example. Other examples may differ from what is described with regard to FIGS. 7A and 7B.

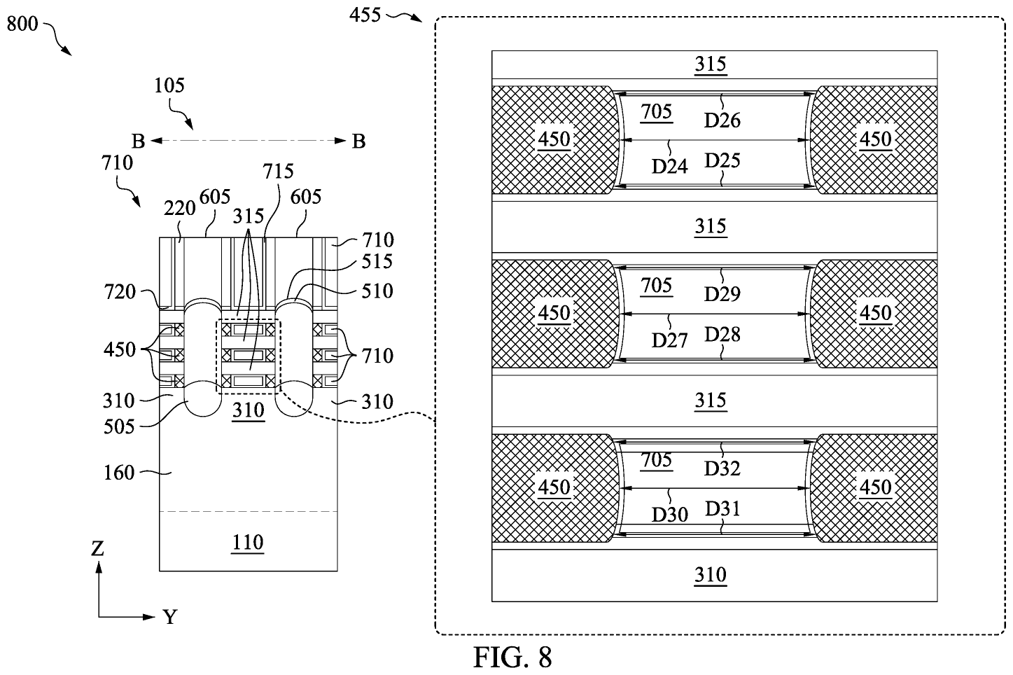

FIG. 8 is a diagram of an example 800 of the semiconductor device 105 described herein. The semiconductor device 105 may be formed using techniques described in connection with FIGS. 1A-7B. As shown in FIG. 8, the semiconductor device 105 includes a plurality of nanostructure channels 315 above a semiconductor substrate 110. The nanostructure channels 315 are arranged in the z-direction, which is perpendicular to the semiconductor substrate 110. The semiconductor device 105 includes a source/drain region 510 adjacent to the nanostructure channels 315. The semiconductor device includes a gate structure 710 wrapping around each of the nanostructure channels 315. Inner spacers 450 are included between the source/drain region 510 and the gate structure 710. The inner spacers 450 are situated between the ends of vertically adjacent nanostructure channels 315. The bottom-most inner spacers 450 may be situated between a mesa region 310 and ends of the bottom-most nanostructure channel 315 above the mesa region 310.

Some intermixing of layers may occur in the semiconductor device 105, such as intermixing between sacrificial nanostructure layers 120 and nanostructure channel layers 125 from which subsequent layers and/or structures were formed in the semiconductor device 105. As a result, silicon regions 135 that have a greater germanium (Ge) content than the germanium content of the nanostructure channels 315 may be located between a nanostructure channel 315 and a portion of the gate structure 710 that wraps around nanostructure channel 315. Moreover, the silicon regions 135 may be included between the nanostructure channel 315 and the inner spacers 450 located on ends of the gate structure 710. The inner spacers 450 may extend into a portion of the silicon region 135 as a result of the one or more second etch operations that are performed in the multiple-etch process for forming the cavities 405. Thus, the thickness of the portion of the silicon region 135 in contact with the gate structure 710 may be greater than the thickness of the portion of the silicon region 135 that is in contact with an inner spacer 450.

One or more dimensions of the semiconductor device 105 are illustrated in a detailed view 805 in FIG. 8. A portion of the gate structure 710 between a top-most nanostructure channel 315 and a middle nanostructure channel 315 under the top-most nanostructure channel 315 may have cross-sectional widths in they-direction corresponding to a dimension D24 (at an approximate center of the portion of the gate structure 710 between adjacent inner spacers 450), a dimension D25 (at a bottom of the portion of the gate structure 710 between adjacent inner spacers 450), and a dimension D26 (at a top of the portion of the gate structure 710 between adjacent inner spacers 450). In some implementations, the difference between the dimension D24 and the dimension D25, and the difference between the dimension D24 and the dimension D26, may be less than approximately 3 nanometers to approximately 0 nanometers as a result of the multiple-etch process for flattening the inner surfaces 415 of the cavities 405 for the inner spacers 450 described herein. For example, the difference between the dimension D24 and the dimension D26, and/or the difference between the dimension D24 and the dimension D25, may be included in a range of approximately 0.5 nanometers to approximately 1.5 nanometers. However, other values and other ranges are within the scope of the present disclosure. The difference between the dimension D24 and the dimension D26, and/or the difference between the dimension D24 and the dimension D25, may be less than a thickness of the z-direction thickness nanostructure channels 315, which may be included in a range of approximately 3 nanometers to approximately 10 nanometers. However, other values for the range are within the scope of the present disclosure. In some implementations, the range of the dimensions D24, D25, and D26 is approximately 12 nanometers to approximately 18 nanometers. However, other values for the range are within the scope of the present disclosure. In some implementations, a ratio of the dimension D24 to the dimension D25, and/or a ratio of the dimension D24 to the dimension D26, is included in a range of approximately 1.03:1 to approximately 1.12:1. However, other values for the range are within the scope of the present disclosure.

Another portion of the gate structure 710 between the middle nanostructure channel 315 and a bottom-most nanostructure channel 315 under the middle nanostructure channel 315 may have cross-sectional widths in they-direction corresponding to a dimension D27 (at an approximate center of the portion of the gate structure 710 between adjacent inner spacers 450), a dimension D28 (at a bottom of the portion of the gate structure 710 between adjacent inner spacers 450), and a dimension D29 (at a top of the portion of the gate structure 710 between adjacent inner spacers 450). The ranges for these dimensions and the associated differences and ratios of these dimensions may be similar to those as described for the dimensions D24, D25 and D26. The difference between the dimension D27 and the dimension D24 may be approximately 0 nanometers to less than approximately 6 nanometers. However, other values for the range are within the scope of the present disclosure. The difference between the dimension D28 and the dimension D25 may be approximately 0 nanometers to less than approximately 6 nanometers. However, other values for the range are within the scope of the present disclosure. The difference between the dimension D29 and the dimension D26 may be approximately 0 nanometers to less than approximately 6 nanometers. However, other values for the range are within the scope of the present disclosure.

Another portion of the gate structure 710 between the bottom-most nanostructure channel 315 and the underlying mesa region 310 may have cross-sectional widths in the y-direction corresponding to a dimension D30 (at an approximate center of the portion of the gate structure 710 between adjacent inner spacers 450), a dimension D31 (at a bottom of the portion of the gate structure 710 between adjacent inner spacers 450), and a dimension D32 (at a top of the portion of the gate structure 710 between adjacent inner spacers 450). The ranges for these dimensions and the associated differences and ratios of these dimensions may be similar to those as described for the dimensions D24, D25 and D26. The difference between the dimension D30 and the dimension D24 may be approximately 0 nanometers to less than approximately 6 nanometers. However, other values for the range are within the scope of the present disclosure. The difference between the dimension D31 and the dimension D25 may be approximately 0 nanometers to less than approximately 6 nanometers. However, other values for the range are within the scope of the present disclosure. The difference between the dimension D32 and the dimension D26 may be approximately 0 nanometers to less than approximately 6 nanometers. However, other values for the range are within the scope of the present disclosure. The difference between the dimension D30 and the dimension D27 may be approximately 0 nanometers to less than approximately 6 nanometers. However, other values for the range are within the scope of the present disclosure. The difference between the dimension D31 and the dimension D28 may be less than approximately 6 nanometers to approximately 0 nanometers. However, other values for the range are within the scope of the present disclosure. The difference between the dimension D32 and the dimension D29 may be approximately 0 nanometers to less than approximately 6 nanometers. However, other values for the range are within the scope of the present disclosure.

As indicated above, FIG. 8 is provided as an example. Other examples may differ from what is described with regard to FIG. 8.

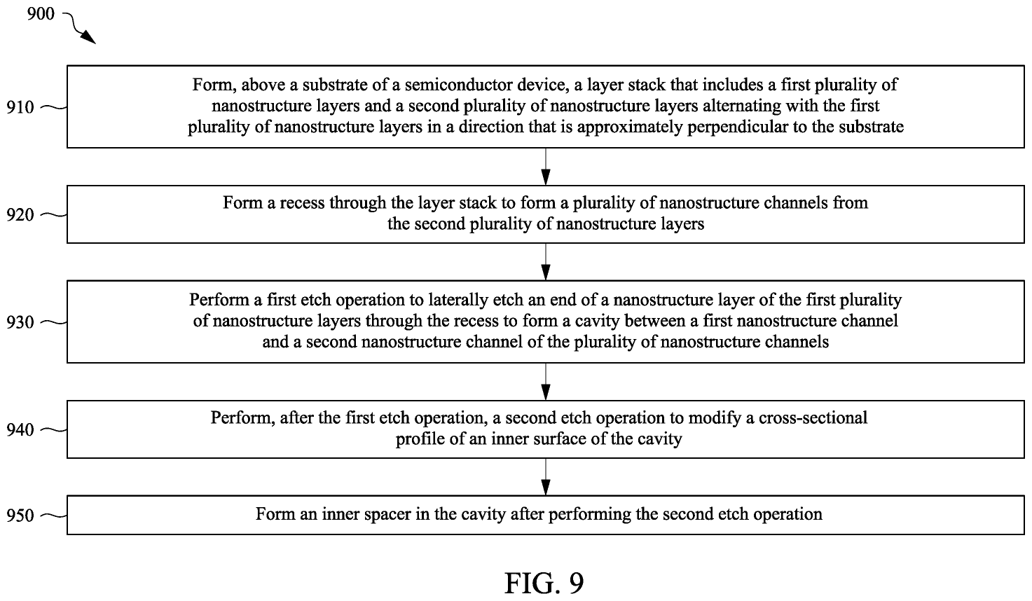

FIG. 9 is a flowchart of an example process 900 associated with forming a semiconductor device. In some implementations, one or more process blocks of FIG. 9 are performed using one or more semiconductor processing tools, such as a deposition tool, an exposure tool, a developer tool, an etch tool, a planarization tool, and/or an ion implantation tool, among other examples.

As shown in FIG. 9, process 900 may include forming, above a substrate of a semiconductor device, a layer stack that includes a first plurality of nanostructure layers and a second plurality of nanostructure layers alternating with the first plurality of nanostructure layers in a direction that is approximately perpendicular to the substrate (block 910). For example, one or more semiconductor processing tools may be used to form, above a substrate (e.g., a semiconductor substrate 110) of a semiconductor device 105, a layer stack 115 that includes a first plurality of nanostructure layers (e.g., sacrificial nanostructure layers 120) and a second plurality of nanostructure layers (e.g., nanostructure channel layers 125) alternating with the first plurality of nanostructure layers in a direction (e.g., z-direction) that is approximately perpendicular to the substrate, as described herein.

As further shown in FIG. 9, process 900 may include forming a recess through the layer stack to form a plurality of nanostructure channels from the second plurality of nanostructure layers (block 920). For example, one or more semiconductor processing tools may be used to form a recess (e.g., a source/drain recess 305) through the layer stack 115 to form a plurality of nanostructure channels 315 from the second plurality of nanostructure layers (e.g., the nanostructure channel layers 125), as described herein. In some implementations, ends of the first plurality of nanostructure layers (e.g., the sacrificial nanostructure layers 120) and ends of the plurality of nanostructure channels 315 are exposed through the recess.

As further shown in FIG. 9, process 900 may include performing a first etch operation to laterally etch an end of a nanostructure layer of the first plurality of nanostructure layers through the recess to form a cavity between a first nanostructure channel and a second nanostructure channel of the plurality of nanostructure channels (block 930). For example, one or more semiconductor processing tools may be used to perform a first etch operation to laterally etch an end of a nanostructure layer (e.g., a sacrificial nanostructure layer 120) of the first plurality of nanostructure layers through the recess (e.g., the source/drain recess 305) to form a cavity 405 between a first nanostructure channel 315 and a second nanostructure channel 315 of the plurality of nanostructure channels 315, as described herein.

As further shown in FIG. 9, process 900 may include performing, after the first etch operation, a second etch operation to modify a cross-sectional profile of an inner surface of the cavity (block 940). For example, one or more semiconductor processing tools may be used to perform, after the first etch operation, a second etch operation to modify a cross-sectional profile of an inner surface 415 of the cavity 405, as described herein.

As further shown in FIG. 9, process 900 may include forming an inner spacer in the cavity after performing the second etch operation (block 950). For example, one or more semiconductor processing tools may be used to form an inner spacer 450 in the cavity 405 after performing the second etch operation, as described herein.

Process 900 may include additional implementations, such as any single implementation or any combination of implementations described below and/or in connection with one or more other processes described elsewhere herein.

In a first implementation, an interface between the nanostructure layer (e.g., the sacrificial nanostructure layer 120) and the first nanostructure channel 315 includes a silicon germanium (SiGe) region 130 having a silicon (Si) concentration that is greater than a silicon concentration in the nanostructure layer (e.g., the sacrificial nanostructure layer 120), and a silicon region 135 having a germanium (Ge) concentration that is greater than a germanium concentration in the first nanostructure channel 315, and performing the second etch operation includes trimming the silicon germanium region 130 and the silicon region 135.

In a second implementation, alone or in combination with the first implementation, the inner surface 415 of the cavity 405 has, after the first etch operation, a first distance (e.g., a dimension D1) between an approximate center point of an arc of the inner surface 415 and an approximate center point of a base 420 of the arc, the inner surface 415 of the cavity 405 has, after the second etch operation, a second distance (e.g., a dimension D6) between the approximate center point of the arc and the approximate center point of the base 420 of the arc, and the second distance is less than the first distance.

In a third implementation, alone or in combination with one or more of the first and second implementations, performing the second etch operation results in flattening of a cross-sectional curvature of the inner surface of the cavity.

In a fourth implementation, alone or in combination with one or more of the first through third implementations, performing the second etch operation includes performing the second etch operation using a gas-based etchant that includes a combination of fluorine (F₂) and ammonia (NH₃).

In a fifth implementation, alone or in combination with one or more of the first through fourth implementations, performing the second etch operation includes providing a first gas flow of fluorine (F₂) into a processing chamber in which the semiconductor device 105 is located, and providing a second gas flow of ammonia (NH₃) into the processing chamber after the first gas flow is stopped.

In a sixth implementation, alone or in combination with one or more of the first through fifth implementations, a difference between a width (D3, D9) at an approximate center of the nanostructure layer and a width (D4, D10) at a bottom of the nanostructure channel less after the second etch operation than prior to the second etch operation.

In a seventh implementation, alone or in combination with one or more of the first through sixth implementations, the inner surface 415 of the cavity 405 has, after the first etch operation, a first angle (e.g., a dimension D2) between an approximate center point 430 of an arc of the inner surface 415 and an end point 435 of the arc, the inner surface 415 of the cavity 405 has, after the second etch operation, a second angle (e.g., a dimension D7) between the approximate center point 430 of arc and the end point 435 of the arc, and the second angle is less than the first angle.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

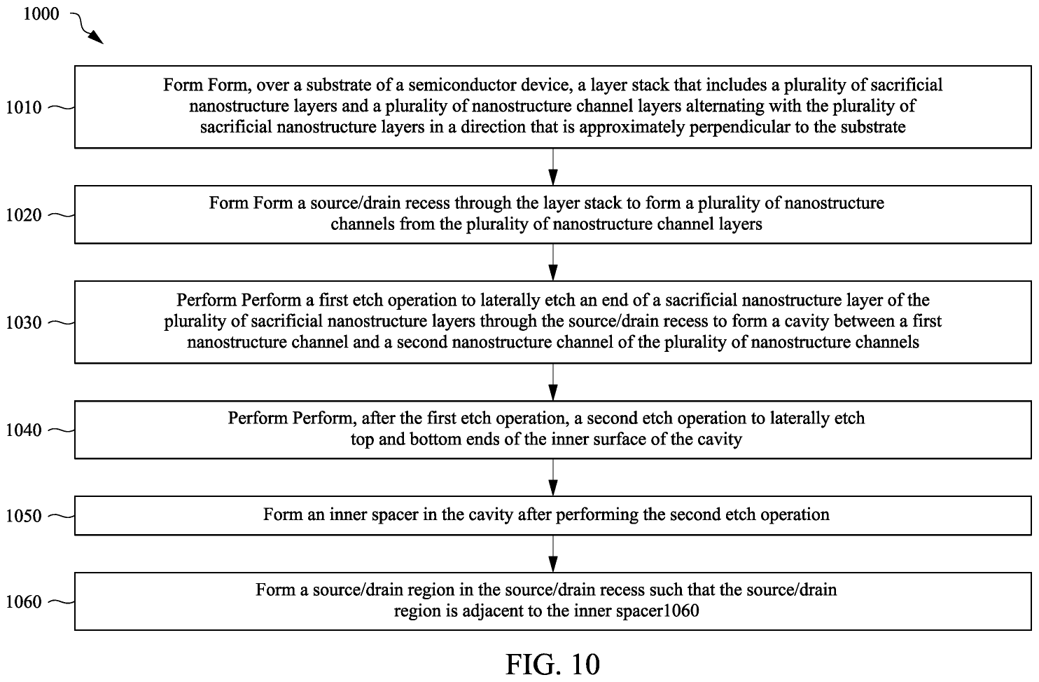

FIG. 10 is a flowchart of an example process 1000 associated with forming a semiconductor device described herein. In some implementations, one or more process blocks of FIG. 10 are performed using one or more semiconductor processing tools, such as a deposition tool, an exposure tool, a developer tool, an etch tool, a planarization tool, and/or an ion implantation tool, among other examples

As shown in FIG. 10, process 1000 may include forming, over a substrate of a semiconductor device, a layer stack that includes a plurality of sacrificial nanostructure layers and a plurality of nanostructure channel layers alternating with the plurality of sacrificial nanostructure layers in a direction that is approximately perpendicular to the substrate (block 1010). For example, one or more semiconductor processing tools may be used to form, over a substrate (e.g., a semiconductor substrate 110) of a semiconductor device 105, a layer stack 115 that includes a plurality of sacrificial nanostructure layers 120 and a plurality of nanostructure channel layers 125 alternating with the plurality of sacrificial nanostructure layers 120 in a direction (e.g., z-direction) that is approximately perpendicular to the substrate, as described herein.

As further shown in FIG. 10, process 1000 may include forming a source/drain recess through the layer stack to form a plurality of nanostructure channels from the plurality of nanostructure channel layers (block 1020). For example, one or more semiconductor processing tools may be used to form a source/drain recess 305 through the layer stack 115 to form a plurality of nanostructure channels 315 from the plurality of nanostructure channel layers 125, as described herein. In some implementations, ends of the plurality of sacrificial nanostructure layers 120 and ends of the plurality of nanostructure channels 315 are exposed through the source/drain recess 305.

As further shown in FIG. 10, process 1000 may include performing a first etch operation to laterally etch an end of a sacrificial nanostructure layer of the plurality of sacrificial nanostructure layers through the source/drain recess to form a cavity between a first nanostructure channel and a second nanostructure channel of the plurality of nanostructure channels (block 1030). For example, one or more semiconductor processing tools may be used to perform a first etch operation to laterally etch an end of a sacrificial nanostructure layer 120 of the plurality of sacrificial nanostructure layers 120 through the source/drain recess 305 to form a cavity 405 between a first nanostructure channel 315 and a second nanostructure channel 315 of the plurality of nanostructure channels 315, as described herein. In some implementations, an inner surface 415 of the cavity 405 has a first radius of curvature after the first etch operation.

As further shown in FIG. 10, process 1000 may include performing, after the first etch operation, a second etch operation to laterally etch top and bottom ends of the inner surface of the cavity (block 1040). For example, one or more semiconductor processing tools may be used to perform, after the first etch operation, a second etch operation to laterally etch top and bottom ends of the inner surface 415 of the cavity 405, as described herein. In some implementations, the inner surface 415 of the cavity 405 has a second radius of curvature, after the second etch operation, that is greater than the first radius of curvature.

As further shown in FIG. 10, process 1000 may include forming an inner spacer in the cavity after performing the second etch operation (block 1050). For example, one or more semiconductor processing tools may be used to form an inner spacer 450 in the cavity 405 after performing the second etch operation, as described herein.

As further shown in FIG. 10, process 1000 may include forming a source/drain region in the source/drain recess such that the source/drain region is adjacent to the inner spacer (block 1060). For example, one or more semiconductor processing tools may be used to form a source/drain region 510 in the source/drain recess 305 such that the source/drain region 510 is adjacent to the inner spacer 450, as described herein.

Process 1000 may include additional implementations, such as any single implementation or any combination of implementations described below and/or in connection with one or more other processes described elsewhere herein.

In a first implementation, an interface between the sacrificial nanostructure layer 120 and the first nanostructure channel 315 includes a silicon germanium (SiGe) region 130 having a silicon (Si) concentration that is greater than a silicon concentration in the sacrificial nanostructure layer 120, and a silicon region 135 having a germanium (Ge) concentration that is greater than a germanium concentration in the first nanostructure channel 315, and performing the second etch operation includes performing a plurality of etch cycles to etch the silicon germanium region 130 and the silicon region 135.

In a second implementation, alone or in combination with the first implementation, the an etch cycle of the plurality of etch cycles includes etching the silicon germanium region 130 and the silicon region 135 using a gas-based etchant that includes a combination of fluorine (F₂) and ammonia (NH₃).

In a third implementation, alone or in combination with one or more of the first and second implementations, the etch cycle includes removing etch byproducts, resulting from the etching the silicon germanium region 130 and the silicon region 135, from a processing chamber in which the semiconductor device 105 is situated.

In a fourth implementation, alone or in combination with one or more of the first through third implementations, the fluorine and the ammonia react with silicon in the silicon germanium region 130 and silicon in the silicon region 135 to form ammonium fluorosilicate ((NH₄)₂SiF₆), and the ammonia etches the ammonium fluorosilicate to etch the silicon germanium region 130 and the silicon region 135.

In a fifth implementation, alone or in combination with one or more of the first through fourth implementations, the fluorine and the ammonia react with germanium in the sacrificial nanostructure layer 120 to form ammonium fluorogermanate ((NH₄)₂GeF₆), and the ammonium fluorogermanate protects the sacrificial nanostructure layer 120 from being etched in the second etch operation.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, inner spacers are formed in a nanostructure transistor of a semiconductor device in a manner that reduces the likelihood of etching through the inner spacers and into an adjacent source/drain region. In particular, a multiple-etch process described herein is performed to form the cavities in which the inner spacers are to be formed. The multiple-etch process includes one or more first etch operations to form the cavities, and one or more second etch operations to trim the corners of the cavities to reduce corner rounding in the corners of the cavities. The corners of the cavities have sharper transitions (e.g., increased orthogonality) between the sidewalls and an inner surface of the cavities as a result of the one or more second etch operations being performed. This results in less variation and increased uniformity in the lateral thickness of the inner spacers that are subsequently formed in the cavities. The increased uniformity in the lateral thickness of the inner spacers reduces the likelihood of etching through any particular part of the inner spacers during a replacement gate operation to replace sacrificial nanostructure layers with the gate structure of the nanostructure transistor. In this way, the techniques described herein may reduce the likelihood of failure of the nanostructure transistor and/or may increase the yield of nanostructure transistors formed on the semiconductor device.

As described in greater detail above, some implementations described herein provide a method. The method includes forming, above a substrate of a semiconductor device, a layer stack that includes a first plurality of nanostructure layers and a second plurality of nanostructure layers alternating with the first plurality of nanostructure layers in a direction that is approximately perpendicular to the substrate. The method includes forming a recess through the layer stack to form a plurality of nanostructure channels from the second plurality of nanostructure layers, where ends of the first plurality of nanostructure layers and ends of the plurality of nanostructure channels are exposed through the recess. The method includes performing a first etch operation to laterally etch an end of a nanostructure layer of the first plurality of nanostructure layers through the recess to form a cavity between a first nanostructure channel and a second nanostructure channel of the plurality of nanostructure channels. The method includes performing, after the first etch operation, a second etch operation to modify a cross-sectional profile of an inner surface of the cavity. The method includes forming an inner spacer in the cavity after performing the second etch operation.

As described in greater detail above, some implementations described herein provide a method. The method includes forming, over a substrate of a semiconductor device, a layer stack that includes a plurality of sacrificial nanostructure layers and a plurality of nanostructure channel layers alternating with the plurality of sacrificial nanostructure layers in a direction that is approximately perpendicular to the substrate. The method includes forming a source/drain recess through the layer stack to form a plurality of nanostructure channels from the plurality of nanostructure layers, where ends of the plurality of sacrificial nanostructure layers and ends of the plurality of nanostructure channels are exposed through the source/drain recess. The method includes performing a first etch operation to laterally etch an end of a sacrificial nanostructure layer of the plurality of sacrificial nanostructure layers through the source/drain recess to form a cavity between a first nanostructure channel and a second nanostructure channel of the plurality of nanostructure channels, where an inner surface of the cavity has a first radius of curvature after the first etch operation. The method includes performing, after the first etch operation, a second etch operation to laterally etch top and bottom ends of the inner surface of the cavity, where the inner surface of the cavity has a second radius of curvature, after the second etch operation, that is greater than the first radius of curvature. The method includes forming an inner spacer in the cavity after performing the second etch operation. The method includes forming a source/drain region in the source/drain recess such that the source/drain region is adjacent to the inner spacer.

As described in greater detail above, some implementations described herein provide a semiconductor device. The semiconductor device includes a plurality of nanostructure channels above a substrate, where the plurality of nanostructure channels are arranged in a direction that is perpendicular to the substrate, and where the plurality of nanostructure channels includes a first nanostructure channel and a second nanostructure channel above the first nanostructure channel. The semiconductor device includes a source/drain region adjacent to the plurality of nanostructure channels. The semiconductor device includes a gate structure wrapping around each of the plurality of nanostructure channels, where a first portion of the gate structure below the first nanostructure channel has a first width at an approximate center of the first portion, where a second portion of the gate structure between the first nanostructure channel and the second nanostructure channel has a second width at an approximate center of the second portion, and where a difference between the second width and a third width, at a top of the second portion adjacent to the second nanostructure channel, is less than a difference between the first width and the second width. The semiconductor device includes a plurality of inner spacers between the source/drain region and the gate structure, where an inner spacer of the plurality of inner spacers, is situated between an end of the first nanostructure channel and an end of the second nanostructure channel.

The terms “approximately” and “substantially” can indicate a value of a given quantity that varies within 5% of the value (e.g., +1%, ±2%, ±3%, ±4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, above a substrate of a semiconductor device, a layer stack that includes a first plurality of nanostructure layers and a second plurality of nanostructure layers alternating with the first plurality of nanostructure layers in a direction that is approximately perpendicular to the substrate;
forming a recess through the layer stack to form a plurality of nanostructure channels from the second plurality of nanostructure layers,
wherein ends of the first plurality of nanostructure layers and ends of the plurality of nanostructure channels are exposed through the recess;
performing a first etch operation to laterally etch an end of a nanostructure layer of the first plurality of nanostructure layers through the recess to form a cavity between a first nanostructure channel and a second nanostructure channel of the plurality of nanostructure channels;
performing, after the first etch operation, a second etch operation to modify a cross-sectional profile of an inner surface of the cavity; and
forming an inner spacer in the cavity after performing the second etch operation.

2. The method of claim 1, wherein an interface between the nanostructure layer and the first nanostructure channel comprises:
a silicon germanium (SiGe) region having a silicon (Si) concentration that is greater than a silicon concentration in the nanostructure layer; and
a silicon region having a germanium (Ge) concentration that is greater than a germanium concentration in the first nanostructure channel; and
wherein performing the second etch operation comprises:
trimming the silicon germanium region and the silicon region.

3. The method of claim 1, wherein the inner surface of the cavity has, after the first etch operation, a first distance between an approximate center point of an arc of the inner surface and an approximate center point of a base of the arc;
wherein the inner surface of the cavity has, after the second etch operation, a second distance between the approximate center point of the arc and the approximate center point of the base of the arc; and
wherein the second distance is less than the first distance.

4. The method of claim 1, wherein performing the second etch operation results in flattening of a cross-sectional curvature of the inner surface of the cavity.

5. The method of claim 1, wherein performing the second etch operation comprises performing the second etch operation using a gas-based etchant that includes a combination of fluorine (F₂) and ammonia (NH₃).

6. The method of claim 1, wherein performing the second etch operation comprises:
providing a first gas flow of fluorine (F₂) into a processing chamber in which the semiconductor device is located; and
providing a second gas flow of ammonia (NH₃) into the processing chamber after the first gas flow is stopped.

7. The method of claim 1, wherein a difference between a width at an approximate center of the nanostructure layer and a width at a bottom of the nanostructure channel less after the second etch operation than prior to the second etch operation.

8. The method of claim 1, wherein the inner surface of the cavity has, after the first etch operation, a first angle between an approximate center point of an arc of the inner surface and an end point of the arc;
wherein the inner surface of the cavity has, after the second etch operation, a second angle between the approximate center point of arc and the end point of the arc; and
wherein the second angle is less than the first angle.

9. A method, comprising:
forming, over a substrate of a semiconductor device, a layer stack that includes a plurality of sacrificial nanostructure layers and a plurality of nanostructure channel layers alternating with the plurality of sacrificial nanostructure layers in a direction that is approximately perpendicular to the substrate;
forming a source/drain recess through the layer stack to form a plurality of nanostructure channels from the plurality of nanostructure channel layers,
wherein ends of the plurality of sacrificial nanostructure layers and ends of the plurality of nanostructure channels are exposed through the source/drain recess;
performing a first etch operation to laterally etch an end of a sacrificial nanostructure layer of the plurality of sacrificial nanostructure layers through the source/drain recess to form a cavity between a first nanostructure channel and a second nanostructure channel of the plurality of nanostructure channels,
wherein an inner surface of the cavity has a first radius of curvature after the first etch operation;
performing, after the first etch operation, a second etch operation to laterally etch top and bottom ends of the inner surface of the cavity,
wherein the inner surface of the cavity has a second radius of curvature, after the second etch operation, that is greater than the first radius of curvature;
forming an inner spacer in the cavity after performing the second etch operation; and
forming a source/drain region in the source/drain recess such that the source/drain region is adjacent to the inner spacer.

10. The method of claim 9, wherein an interface between the sacrificial nanostructure layer and the first nanostructure channel comprises:
a silicon germanium (SiGe) region having a silicon (Si) concentration that is greater than a silicon concentration in the sacrificial nanostructure layer; and
a silicon region having a germanium (Ge) concentration that is greater than a germanium concentration in the first nanostructure channel; and
wherein performing the second etch operation comprises:
performing a plurality of etch cycles to etch the silicon germanium region and the silicon region.

11. The method of claim 10, wherein the an etch cycle of the plurality of etch cycles comprises etching the silicon germanium region and the silicon region using a gas-based etchant that includes a combination of fluorine (F₂) and ammonia (NH₃).

12. The method of claim 11, wherein the etch cycle comprises removing etch byproducts, resulting from the etching the silicon germanium region and the silicon region, from a processing chamber in which the semiconductor device is situated.

13. The method of claim 11, wherein the fluorine and the ammonia react with silicon in the silicon germanium region and silicon in the silicon region to form ammonium fluorosilicate ((NH₄)₂SiF₆); and
wherein the ammonia etches the ammonium fluorosilicate to etch the silicon germanium region and the silicon region.

14. The method of claim 11, wherein the fluorine and the ammonia react with germanium in the sacrificial nanostructure layer to form ammonium fluorogermanate ((NH₄)₂GeF₆); and
wherein the ammonium fluorogermanate protects the sacrificial nanostructure layer from being etched in the second etch operation.

15. A semiconductor device, comprising:
a plurality of nanostructure channels above a substrate,
wherein the plurality of nanostructure channels are arranged in a direction that is perpendicular to the substrate, and
wherein the plurality of nanostructure channels comprises:
a first nanostructure channel; and
a second nanostructure channel above the first nanostructure channel;
a source/drain region adjacent to the plurality of nanostructure channels;
a gate structure wrapping around each of the plurality of nanostructure channels,
wherein a first portion of the gate structure below the first nanostructure channel has a first width at an approximate center of the first portion,
wherein a second portion of the gate structure between the first nanostructure channel and the second nanostructure channel has a second width at an approximate center of the second portion, and
wherein a difference between the second width and a third width, at a top of the second portion adjacent to the second nanostructure channel, is less than a difference between the first width and the second width; and
a plurality of inner spacers between the source/drain region and the gate structure,
wherein an inner spacer of the plurality of inner spacers, is situated between an end of the first nanostructure channel and an end of the second nanostructure channel.

16. The semiconductor device of claim 15, wherein the difference between the second width and a third width is less than approximately 3 nanometers.

17. The semiconductor device of claim 16, wherein the difference between the first width and the second width is less than approximately 6 nanometers.

18. The semiconductor device of claim 15, wherein the difference between the second width and a third width is less than a thickness of the second nanostructure channel.

19. The semiconductor device of claim 15, wherein a difference, between fourth width at an approximate center of the inner spacer and fifth width at a top of the inner spacer is included in a range of approximately 0.5 nanometers to approximately 1.5 nanometer.

20. The semiconductor device of claim 15, further comprising:
a silicon region between the first nanostructure channel and the inner spacer,
wherein the inner spacer extends into a portion of the silicon region.
